(19) United States
(12) Patent Application Publication
(10) Pub. No.: US 2025/0234562 A1
(43) Pub. Date: Jul. 17, 2025

(54) SEMICONDUCTOR DEVICE, AND SEMICONDUCTOR PACKAGE AND ELECTRONIC SYSTEM INCLUDING THE SAME

(71) Applicant: SAMSUNG ELECTRONICS CO., LTD., Suwon-si (KR)

(72) Inventors: Siwan Kim, Suwon-si (KR); Joonyoung Kwon, Suwon-si (KR); Junhyoung Kim, Suwon-si (KR); Jiyoung Kim, Suwon-si (KR); Sukkang Sung, Suwon-si (KR)

(21) Appl. No.: 18/797,102

(22) Filed: Aug. 7, 2024

(30) Foreign Application Priority Data
Jan. 11, 2024 (KR) 10-2024-0004893

(51) Int. Cl. H10B 80/00; H01L 23/00; H01L 23/48; H01L 23/538

(52) U.S. Cl. CPC H10B 80/00; H01L 23/481; H01L 24/16; H01L 24/17; H01L 23/5383; H01L 24/32; H01L 24/33; H01L 24/73; H01L 2224/16146; H01L 2224/16227; H01L 2224/17181; H01L 2224/32145; H01L 2224/32225; H01L 2224/33181; H01L 2224/73203

(57) ABSTRACT

A semiconductor device includes a circuit region including a pad region, and a cell region including a memory cell structure on the circuit region. The semiconductor device includes a stacked region where the cell region is stacked on the circuit region and a non-stacked region where the pad region of the circuit region is positioned outside the stacked region. The semiconductor device further includes a plurality of the semiconductor devices stacked atop each other and electrically connected to each other in the pad regions. A bonding layer is between adjacently stacked devices.

### CROSS-REFERENCE TO RELATED APPLICATION

This application claims priority to and the benefit of Korean Patent Application No. 10-2024-0004893 filed in the Korean Intellectual Property Office on Jan. 11, 2024, the entire contents of which are incorporated herein by reference.

### BACKGROUND

In an electron system implementing a data storage, a semiconductor device capable of storing high-capacity data is in demand. Accordingly, a method for increasing a data storage capacity of a semiconductor device is being researched. As one method for increasing the data storage capacity of a semiconductor device, a semiconductor device including three-dimensionally arranged memory cells instead of two-dimensionally arranged memory cells has been proposed.

### SUMMARY

The present disclosure is directed to a semiconductor device capable of reducing a thickness of a semiconductor package and enhancing performance, and a semiconductor package and an electronic system including the same.

A semiconductor device according to some implementations includes a circuit region including a pad region, and a cell region including a memory cell structure on the circuit region. The semiconductor device includes a stacked region where the cell region is stacked on the circuit region and a non-stacked region where the pad region of the circuit region is positioned outside the stacked region.

A semiconductor package according to some implementations includes a plurality of semiconductor devices including a first semiconductor device and a second semiconductor device. The first semiconductor device includes a first stacked region where a first cell region including a first memory cell structure is on a first circuit region and a first non-stacked region where a first pad region of the first circuit region is positioned outside the first stacked region. The second semiconductor device includes a second stacked region where a second cell region including a second memory cell structure is on a second circuit region and a second non-stacked region where a second pad region of the second circuit region is positioned outside the second stacked region. The first semiconductor device and the second semiconductor device are electrically connected to each other by stacking the second pad region on the first pad region.

An electronic system includes a main substrate, a semiconductor device on the main substrate, and a controller electrically connected to the semiconductor device on the main substrate. The semiconductor device includes a circuit region including a pad region, and a cell region including a memory cell structure on the circuit region. The semiconductor device includes a stacked region where the cell region is stacked on the circuit region and a non-stacked region where the pad region of the circuit region is positioned outside the stacked region.

According some implementations, a plurality of semiconductor devices may be connected by using a pad region in a non-stacked region having a relatively small thickness to manufacture a semiconductor package. Accordingly, a thickness of a semiconductor package may be reduced. More particularly, the thickness of the semiconductor package may be effectively reduced when a number of gate electrodes is increased to increase a data storage capacity of the semiconductor device.

In this instance, the plurality of semiconductor devices may be electrically connected to each other by a through connecting portion included in the pad region, thereby shortening a signal path and reducing a problem such as a signal loss. Accordingly, performance of the semiconductor device or the semiconductor package may be enhanced.

### BRIEF DESCRIPTION OF THE DRAWINGS

FIG. 1 is a plan view schematically illustrating a semiconductor device according to some implementations.

FIG. 2 is a cross-sectional view schematically illustrating the semiconductor device taken along line A-A′ in FIG. 1.

FIG. 3 is an enlarged cross-sectional view illustrating a partial portion of a circuit region and a cell region included in the semiconductor device illustrated in FIG. 1.

FIG. 4 is a perspective view schematically illustrating a semiconductor package according to some implementations.

FIG. 5 is a cross-sectional view illustrating the semiconductor package taken along line D-D′ in FIG. 4.

FIG. 6 is a development view illustrating a plurality of semiconductor devices included in the semiconductor package illustrated in FIG. 4 to have a gap therebetween.

FIG. 7 is development view illustrating a plurality of semiconductor devices included in a semiconductor package according to a modified embodiment to have a gap therebetween.

FIG. 8 is a plan view schematically illustrating a process forming a preliminary circuit substrate including a plurality of preliminary circuit regions corresponding to a plurality of semiconductor devices included in a semiconductor package.

FIG. 9 is a perspective view schematically illustrating a semiconductor device and a semiconductor package including the same according to some implementations.

FIG. 10 is a cross-sectional view illustrating the semiconductor package taken along line E-E′ in FIG. 9.

FIG. 11 is a development view illustrating a plurality of semiconductor devices included in the semiconductor package illustrated in FIG. 9 to have a gap therebetween.

FIG. 12 is a perspective view schematically illustrating a semiconductor device and a semiconductor package including the same according to some implementations.

FIG. 13 is a cross-sectional view illustrating the semiconductor package taken along line F-F′ in FIG. 12.

FIG. 14 is a development view illustrating a plurality of semiconductor devices included in the semiconductor package illustrated in FIG. 12 to have a gap therebetween.

FIG. 15 is a partial cross-sectional view schematically illustrating a semiconductor device according to some implementations.

FIG. 16 schematically illustrates an electronic system including a semiconductor device according to some implementations.

FIG. 17 is a perspective view schematically illustrating an electronic system including a semiconductor device according to some implementations.

FIG. 18 is a cross-sectional view schematically illustrating a semiconductor package according to some implementations.

### DETAILED DESCRIPTION

Implementations of the present disclosure will be described more fully hereinafter with reference to the accompanying drawings for those skilled in the art to which the present disclosure pertains to easily practice the present disclosure. The present disclosure may be implemented in various different forms and is not limited to the example implementations provided herein.

A portion unrelated to the description is omitted in order to clearly describe the present disclosure, and the same or similar components are denoted by the same reference numeral throughout the present specification.

Further, since sizes and thicknesses of portions, regions, members, units, layers, films, etc. illustrated in the accompanying drawings may be arbitrarily illustrated for better understanding and convenience of explanation, the present disclosure is not limited to the illustrated sizes and thicknesses. In the drawings, thicknesses of portions, regions, members, units, layers, films, etc. may be enlarged or exaggerated for convenience of explanation.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, and variations such as “comprises” or “comprising”, will be understood to imply the inclusion of stated elements but not the exclusion of any other elements.

Further, throughout the specification, a phrase “on a plane”, “in a plane”, “on a plan view”, or “in a plan view” may indicate a case where a portion is viewed from above or a top portion, and a phrase “on a cross-section” or “in a cross-section” may indicate when a cross-section taken along a vertical direction is viewed from a side.

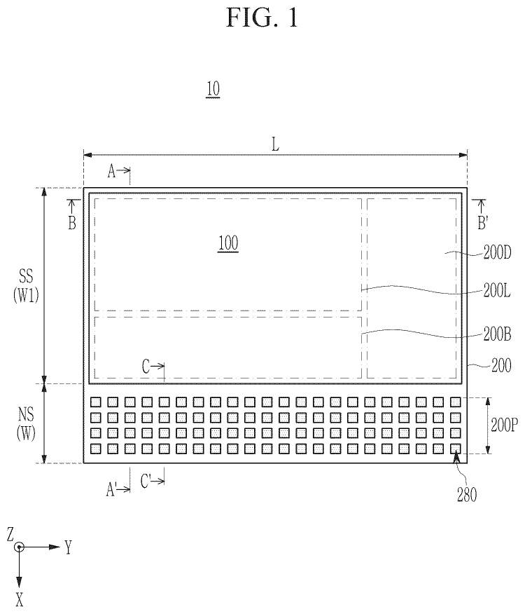

Hereinafter, with reference to FIG. 1 to FIG. 8, a semiconductor device and a semiconductor package including the same according to implementations will be described in detail.

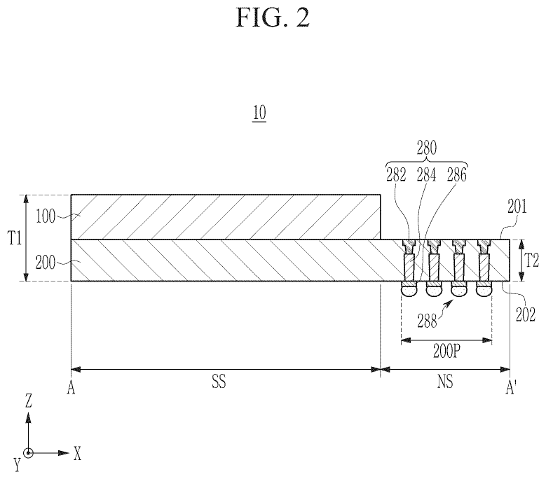

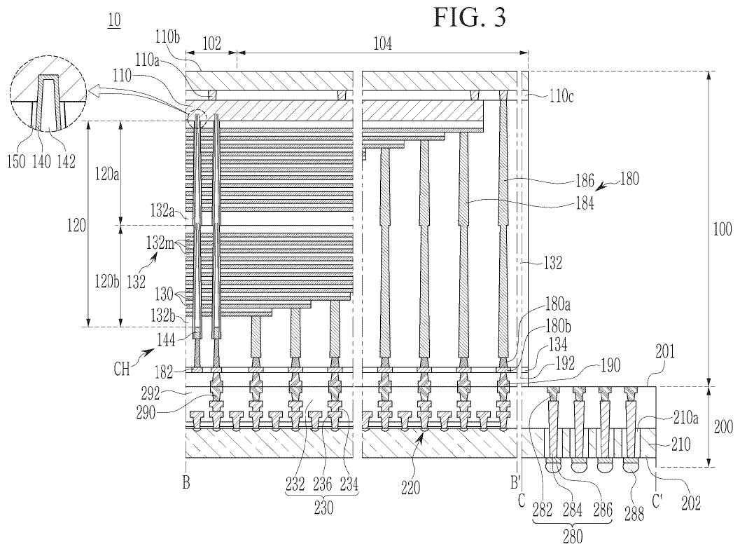

FIG. 1 is a plan view schematically illustrating a semiconductor device 10 according to implementations. FIG. 2 is a cross-sectional view schematically illustrating the semiconductor device 10 taken along line A-A′ in FIG. 1. FIG. 3 is an enlarged cross-sectional view illustrating a partial portion of a circuit region 200 and a cell region 100 included in the semiconductor device 10 illustrated in FIG. 1. In FIG. 3, a cross-sectional view of the cell region 100 taken along line B-B′ in FIG. 1 is illustrated, and a cross-sectional view of a pad region 200P of the circuit region 200 taken along line C-C′ in FIG. 1 is illustrated.

For simple illustration and a clear understanding, it is illustrated that a thickness of the cell region 100 is greater than a thickness of the circuit region 200 in FIG. 3, but the implementations are not limited thereto. The thickness of the circuit region 200 may be less than the thickness of the cell region 100, be the same as the thickness of the cell region 100, or be greater than the thickness of the cell region 100. In implementations, the thickness of the circuit region 200 may be the same as the thickness of the cell region 100 or be greater than the thickness of the cell region 100.

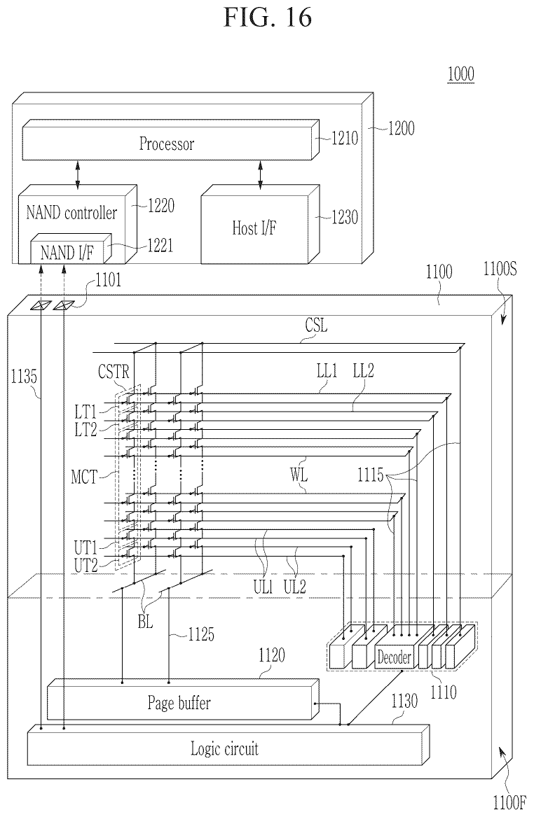

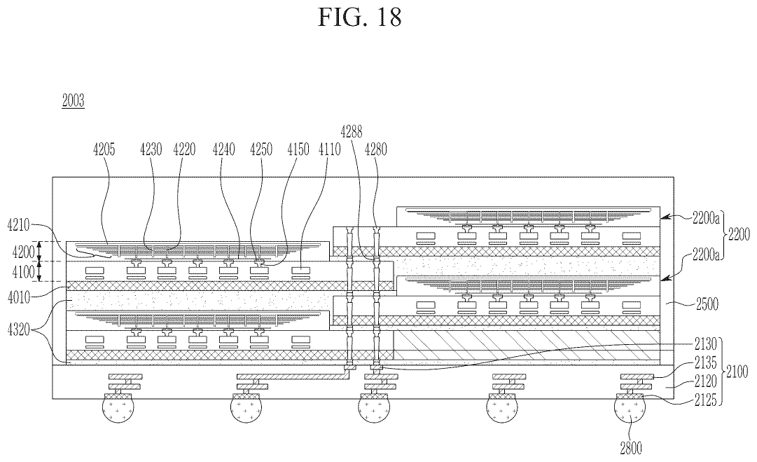

Referring to FIG. 1 to FIG. 3, a semiconductor device 10 according to implementations may include a circuit region 200 including a pad region 200P, and a cell region 100 including a memory cell structure on the circuit region 200. In this instance, the semiconductor device 10 may include a stacked region SS where the cell region 100 is stacked on the circuit region 200 and a non-stacked region NS where the pad region 200P of the circuit region 200 is positioned outside the stacked region SS. For example, the circuit region 200 and the cell region 100 may correspond to a first structure 1100F and a second structure 1100S of a semiconductor device 1100 included in an electronic system 1000 illustrated in FIG. 16, respectively. For example, the circuit region 200 and the cell region 100 may be portions including a first structure 4100 and a second structure 4200 of a semiconductor chip 2200a illustrated in FIG. 18, respectively.

The circuit region 200 may include a peripheral circuit structure for controlling the memory cell structure. The cell region 100 may include a gate stacking structure 120 and a channel structure CH as the memory cell structure on a second substrate 110. The circuit region 200 may include a first wiring portion 230, and the cell region 100 may include a second wiring portion 180 electrically connected to the memory cell structure.

In implementations, the cell region 100 may be on the circuit region 200. Accordingly, an area corresponding to the circuit region 200 does not need to be secured separately from the cell region 100. Therefore, an area of the semiconductor device 10 may be reduced. However, the implementations are not limited thereto, and the circuit region 200 may be disposed next to the cell region 100. Various other modifications are possible.

The circuit region 200 may include a first substrate 210, and a circuit element 220, a first wiring portion 230, and a first bonding structure 290 electrically connected to the first wiring portion 230 and positioned at a first surface 201 facing the cell region 100. A peripheral area of the first bonding structure 290 at the first surface 201 of the circuit region 200 may be covered by a first bonding insulation layer 292.

The first substrate 210 may be a semiconductor substrate including a semiconductor material. For example, the first substrate 210 may be a semiconductor substrate including or formed of a semiconductor material or may be a semiconductor substrate in which a semiconductor layer is on a base substrate. For example, the first substrate 210 may include single-crystalline or polycrystalline silicon, epitaxial silicon, germanium, silicon-germanium, silicon on insulator (SOI), germanium on insulator (GOI), or so on.

The circuit element 220 on the first substrate 210 may include any of various circuit elements that control an operation of the memory cell structure in the cell region 100. For example, the circuit element 220 may constitute the peripheral circuit structure such as a logic circuit 200L, a decoder circuit 200D, a page buffer 200B, or so on.

The circuit element 220 may include a transistor, but the implementations are not limited thereto. The circuit element 220 may include not only an active element such as the transistor or so on but also a passive element such as a capacitor, a resistor, an inductor, or so on.

The first wiring portion 230 on the first substrate 210 may be electrically connected to the circuit element 220. In implementations, the first wiring portion 230 may include a plurality of wiring layers 236 that are spaced apart from each other while interposing an insulation layer 232 therebetween and are electrically connected by a contact via 234 to form a desired path. The wiring layer 236 or the contact via 234 may include any of various conductive materials, and the insulation layer 232 may include any of various insulating materials.

The cell region 100 may include a second substrate 110, a gate stacking structure 120, a channel structure CH, a second wiring portion 180, and a second bonding structure 190 electrically connected to the second wiring portion 180 and positioned at a surface facing the circuit region 200. A peripheral area of the second bonding structure 190 may be covered by a second bonding insulation layer 192.

In implementations, a source connecting portion 110b may be provided at a side of an outer surface of the second substrate 110. The source connecting portion 110b may be connected to the second substrate 110 through a through via 110a that passes through an outer insulation layer 110c. In this instance, a source contact portion 186 may be connected to the source connecting portion 110b through the through via 110a or be directly connected to the source connecting portion 110b.

The source connecting portion 110b and/or the through via 110a may include or be formed of a conductive material having an electrical resistance less than an electrical resistance of the second substrate 110. For example, the source connecting portion 110b may include a metal material such as tungsten (W), copper (Cu), aluminum (Al), or so on.

When current flows through the second substrate 110, which acts as a common source line, a voltage drop or noise may occur due to the electrical resistance of the second substrate 110, and thus, an operation (e.g., read operation) of a memory cell might not be performed smoothly. Accordingly, the source connecting portion 110b connected to the second substrate 110 and having the electrical resistance less than the electrical resistance of the second substrate 110 is further provided to provide an electrical connection path having a low electrical resistance. The source connecting portion 110b may have any of various shapes providing the electrical connection path, and the implementations are not limited thereto.

The cell region 100 may include a cell array region 102 and a connection region 104. The gate stacking structure 120 and the channel structure CH may be on the second substrate 110. A structure that connects the gate stacking structure 120 and/or the channel structure CH in the cell array region 102 to the circuit region 200 or an external circuit may be in the cell array region 102 and/or the connection region 104.

In implementations, the second substrate 110 may include a semiconductor layer including a semiconductor material. For example, the second substrate 110 may be a semiconductor substrate including or formed of a semiconductor material or may be a semiconductor substrate in which a semiconductor layer is on a base substrate. For example, the second substrate 110 may include or be formed of silicon, germanium, silicon-germanium, silicon on insulator, germanium on insulator, or so on. Here, the semiconductor layer included in the second substrate 110 may be doped with a p-type dopant (such as boron (B), gallium (Ga), or so on) or an n-type dopant (such as phosphorus (P), arsenic (As), or so on). In some implementations, the second substrate 110 may be or include a support member including an insulation layer or an insulating material. This is because, after the cell region 100 is bonded to the circuit region 200, a semiconductor substrate included in the cell region 100 may be removed and the support member including the insulation layer or the insulating material may be formed. However, the implementations are not limited to a material of the second substrate 110, a conductive type of the dopant doped to the semiconductor layer, or so on.

In the cell array region 102, the gate stacking structure 120 and the channel structure CH may be positioned. The gate stacking structure 120 may include cell insulation layers 132 and gate electrodes 130 alternately stacked on a first surface (e.g., a front surface or an upper surface) of the second substrate 110. The channel structure CH may extend in a direction crossing the second substrate 110 while passing through the gate stacking structure 120.

The cell insulation layer 132 may include an interlayer insulation layer 132m and an upper insulation layer 132a or 132b. The interlayer insulation layer 132m may be between two gate electrodes 130 adjacent to each other in each of a plurality of the gate stacking structures 120a and 120b. The upper insulation layers 132a and 132b may be at upper surfaces of the plurality of the gate stacking structures 120a and 120b, respectively. For example, a thickness of the upper insulation layer 132a or 132b may be greater than a thickness of the interlayer insulation layer 132m. For simple illustration, it is illustrated as an example in FIG. 3 that the cell insulation layer 132 is provided as one without a boundary in a partial portion of the connection region 104. However, one or a plurality of insulation layers having various stacking structures may be in the connection region 104. A shape, a structure, or so on of the cell insulation layer 132 may be variously modified in some implementations.

The gate electrode 130 may include any of various conductive materials. For example, the gate electrode 130 may include a metal material (e.g., tungsten (W), copper (Cu), aluminum (Al), or so on), polycrystalline silicon, metal nitride (e.g., titanium nitride (TiN), tantalum nitride (TaN), or so on), or a combination thereof. A partial portion of a blocking layer (e.g., a first blocking layer) including an insulating material may be outside the gate electrode 130. The cell insulation layer 132 may include any of various insulating materials. For example, the cell insulation layer 132 may include silicon oxide, silicon nitride, silicon oxynitride, a low dielectric constant material having a lower dielectric constant than silicon oxide, or a combination thereof.

In implementations, the gate stacking structure 120 may include a plurality of gate stacking structures 120a and 120b sequentially stacked on the second substrate 110. Then, a number of stacked gate electrodes 130 may be increased and thus a number of memory cells may be increased with a stable structure. Accordingly, a data storage capacity of the semiconductor device 10 may be increased. In FIG. 3, it is illustrated as an example that the gate stacking structure 120 includes first and second gate stacking structures 120a and 120b. However, the implementations are not limited thereto. In some implementations, the gate stacking structure 120 may include one gate stacking structure or three or more gate stacking structures.

In implementations, the channel structure CH may be provided. The channel structure CH may pass through the gate stacking structure 120 and extend in a direction crossing the second substrate 110 (e.g., a vertical direction perpendicular to the second substrate 110 or the Z-axis direction in the drawings).

The channel structure CH may include a channel layer 140, and a gate dielectric layer 150 on the channel layer 140 between the gate electrode 130 and the channel layer 140. The channel structure CH may further include a core insulation layer 142 at an inside of the channel layer 140. In some implementations, the core insulation layer 142 might not be provided. The channel structure CH may further include a channel pad 144 on the channel layer 140 and/or the gate dielectric layer 150. The gate dielectric layer 150 between the gate electrode 130 and the channel layer 140 may include a tunneling layer (not pictured), a charge storage layer (not pictured), and a blocking layer (not pictured) sequentially on the channel layer 140.

Each channel structure CH may form one memory cell string, and a plurality of channel structures CH may be spaced apart from each other while forming rows and columns in a plan view. For example, in a cross-sectional view, the channel structure CH may have an inclined side surface so that a width of the channel structure CH decreases as the channel structure CH goes to the second substrate 110 according to a high aspect ratio. However, the implementations are not limited thereto, and an arrangement, a structure, a shape, or so on of the channel structure CH may be variously modified.

The channel layer 140 may include a semiconductor material (e.g., polycrystalline silicon). The core insulation layer 142 may include any of various insulating materials. For example, the core insulation layer 142 may include silicon oxide, silicon nitride, silicon oxynitride, or a combination thereof. The channel pad 144 may be electrically connected to the channel layer 140. The channel pad 144 may include a conductive material (e.g., polycrystalline or single-crystalline silicon doped with a dopant). However, the implementations are not limited to a structure, a material, or so on of the channel layer 140, the core insulation layer 142, and the channel pad 144.

The tunneling layer is a layer through which charge tunneling occurs according to a voltage applied to the gate electrode 130. The tunneling layer may include an insulating material that is capable of tunneling a charge. The charge storage layer between the tunneling layer and the blocking layer may be used as a data storage region. The blocking layer may include an insulating material that is capable of preventing an undesirable flow of charge into the gate electrode 130. A layer and a material included in the gate dielectric layer 150 may be variously modified.

In implementations, the gate stacking structure 120 may be sequentially stacked on a lower portion of the second substrate 110 in the drawing. Accordingly, in the drawing, the channel structure CH passing through the gate stacking structure 120 may be at a lower portion of the second substrate 110. In a cross-sectional view, the channel structure CH may have an inclined side surface such that a width of the channel structure CH decreases as the channel structure CH goes from the circuit region 200 to the second substrate 110. The channel pad 144 and the second wiring portion 180 at an upper portion of the gate stacking structure 120 may be adjacent to the circuit region 200.

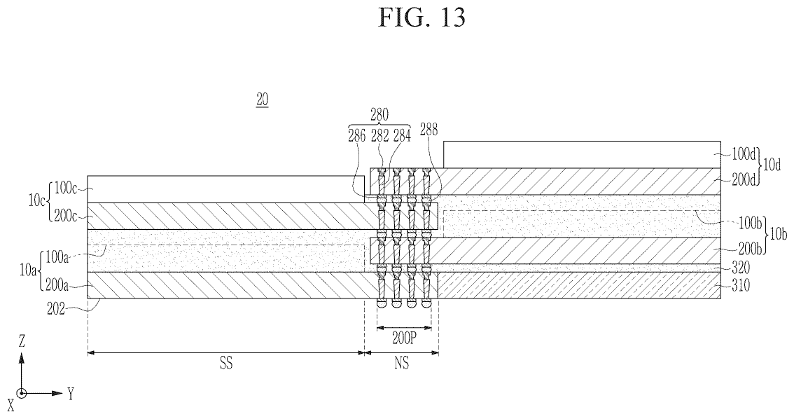

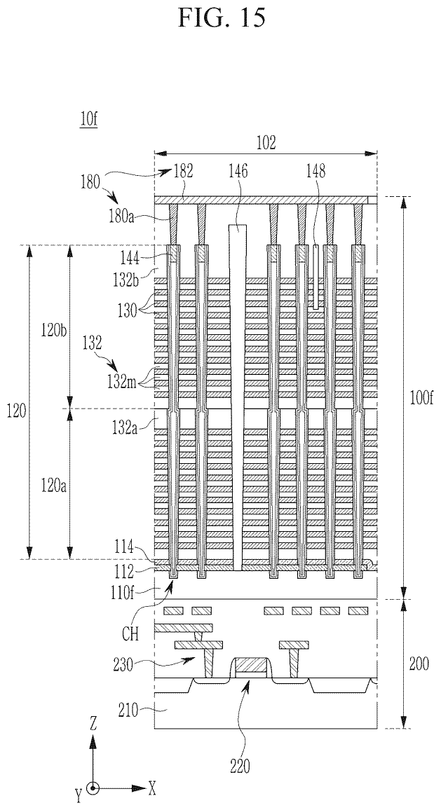

In implementations, the gate stacking structure 120 may be divided into a plurality of portions in a plan view by a separation structure 146 (refer to FIG. 15) extending in a direction crossing the second substrate 110 (e.g., in a vertical direction perpendicular to the second substrate 110 or the Z-axis direction in the drawings) to pass through the gate stacking structure 120. An upper separation region 148 (refer to FIG. 15) may be at an upper portion (a lower portion in FIG. 13) of the gate stacking structure 120. In a plan view, the separation structure 146 and/or the upper separation region 148 may extend in an extension direction of the gate electrode 130 (a Y-axis direction in the drawings). A plurality of separation structures 146 and/or a plurality of upper separation regions 148 may be spaced apart from each other at predetermined intervals in a transverse direction (an X-axis direction in the drawings) that is transverse to the extension direction of the gate electrode 130. The separation structure 146 and/or the upper separation region 148 may be filled with any of various insulating materials.

In implementations, the second wiring portion 180 may include a member electrically connecting the gate electrode 130, the channel structure CH, the second substrate 110, and/or the source connecting portion 110b to the circuit region 200 or the external circuit. For example, the second wiring portion 180 may include a bit line 182, a gate contact portion 184, a source contact portion 186, a contact via 180a connected to each of the bit line 182, the gate contact portion 184, and the source contact portion 186, and a connection wiring 180b connecting the bit line 182, the gate contact portion 184, the source contact portion 186, and the contact via 180a.

The bit line 182 may extend in the transverse direction (the X-axis direction in the drawings) that is transverse to the extension direction of the gate electrode 130. The bit line 182 may be electrically connected to the channel structure CH (e.g., the channel pad 144) through the contact via 180a (e.g., a bit line contact via) that passes through the cell insulation layer 132.

In the connection region 104, the plurality of gate electrodes 130 may extend in the extension direction of the gate electrode 130 (the Y-axis direction in the drawing). Extension lengths of the plurality of gate electrodes 130 may sequentially decrease in a direction away from the second substrate 110. For example, the plurality of gate electrodes 130 may have a stair shape in one direction or a plurality of directions in the connection region 104. In the connection region 104, a plurality of gate contact portions 184 may pass through the cell insulation layer 132 to be electrically connected to the plurality of gate electrodes 130, respectively, extended to the connection region 104.

The source contact portion 186 may be electrically connected to the source connecting portion 110b and/or the second substrate 110 constituting at least a part of a common source line.

The connection wiring 180b may be positioned in the cell array area 102 and/or the connection area 104. The bit line 182, the gate contact portion 184, and/or the source contact portion 186 may be electrically connected to the connection wiring 180b. For example, the gate contact portion 184, and/or the source contact portion 186 may be electrically connected to the connection wiring 180b through the contact via 180a.

In FIG. 3, it is illustrated as an example that the connection wiring 180b is a single layer on the same plane as the bit line 182 and an additional insulation layer 134 is at a portion other than the connection wiring 180b. However, this is a brief illustration for convenience. For an electrical connection with the bit line 182, the gate contact portion 184, and/or the source contact portion 186, the connection wiring 180b may include a plurality of wiring layers and may further include a contact via.

The circuit region 200 may include the first bonding structure 290 electrically connected to the first wiring portion 230 and positioned at a surface facing the cell region 100. The peripheral area of the first bonding structure 290 at the surface of the circuit region 200 facing the cell region 100 may be covered by the first bonding insulation layer 292. The cell region 100 may include the second bonding structure 190 electrically connected to the second wiring portion 180 and positioned at a surface facing the circuit region 200. The peripheral area of the second bonding structure 190 at the surface of the cell region 100 facing the circuit region 200 may be covered by the second bonding insulation layer 192.

The circuit region 200 and the cell region 100 may be bonded by hybrid bonding. More particularly, the circuit region 200 and the cell region 100 may be bonded by the hybrid bonding including metal bonding between the first bonding structure 290 and the second bonding structure 190 and insulation-layer bonding between first bonding insulation layer 292 and the second bonding insulation layer 192.

For example, the first boding structure 290 and/or the second bonding structure 190 may include at least one of copper, aluminum, tungsten, nickel, gold, tin, manganese, cobalt, titanium, tantalum, ruthenium, or beryllium, or an alloy including the same. For example, the first and second bonding structures 290 and 190 may include copper so that the cell region 100 and the circuit region 200 may be bonded (e.g., directly bonded) to each other by copper-to-copper bonding.

For example, at an insulation-layer bonding surface, the first bonding insulation layer 292 and the second bonding insulation layer 192 may include the same insulating material. For example, the first bonding insulation layer 292 and/or the second bonding insulation layer 192 may include a layer including silicon carbonitride at least at the bonding surface. However, the implementations are not limited thereto. The first boding insulation layer 292 and/or the second bonding insulation layer 192 may include the same material as or a different material from the cell insulation layer 132 or the additional insulation layer 134 in the cell region 100 or the insulation layer 232 in the circuit region 200.

In implementations, by the second wiring portion 180, the second bonding structure 190, the first bonding structure 290, and the first wiring portion 230, the bit line 182 connected to the channel structure CH, the gate electrode 130, the second substrate 110, and/or the source connecting portion 110b may be electrically connected to the circuit element 220 of the circuit region 200.

In some implementation, the semiconductor device 10 may include an input/output pad connected to the cell region 100 and/or the circuit region 200, and an input/output connection wiring electrically connected to the input/output pad. For example, at least one of a plurality of first bonding structures 290 may constitute the input/output pad, or the input/output connection wiring may be electrically connected to at least one of the plurality of first bonding structures 290 may constitute the input/output pad. Various other modifications are possible.

In implementations, the circuit region 200 may include the pad region 200P, and may further include the decoder circuit 200D, the page buffer 200B, the logic circuit 200L, or so on. Here, the pad region 200P may be a portion for connection with another semiconductor device 10. The decoder circuit 200D and the page buffer 200B may perform a control operation on at least one selected memory cell of a plurality of memory cell structures, and the logic circuit 200L may perform a control operation on the decoder circuit 200D and the page buffer 200B.

In implementations, the semiconductor device 10 may include a stacked region SS where the cell region 100 is stacked on the circuit region 200 and a non-stacked region NS where the pad region 200P of the circuit region 200 is positioned outside the stacked region SS in a plan view. In a plan view, the circuit region 200 in the non-stacked region NS may have a shape protruding from the circuit region 200 in the stacked region SS to an outside. The non-stacked region NS may be positioned at an edge portion of the semiconductor device 10 and thus may be referred to as an edge region or an end region.

The cell region 100 is in the stacked region SS, but not in the non-stacked region NS. In a plan view, an area of circuit region 200 may be greater than an area of the cell region 100. A second thickness T2 of the non-stacked region NS including the circuit region 200 may be less than a first thickness T1 of the stacked region SS including the cell region 100 and the circuit region 200. In this instance, the first thickness T1 of the stacked region SS may be a thickness in a vertical direction (the Z-axis direction in the drawing) perpendicular to the first substrate 210 or the second substrate 110. For example, the first thickness T1 of the stacked region SS may be a maximum thickness of the stacked region SS. The second thickness T2 of the non-stacked region NS may be a thickness in the vertical direction (the Z-axis direction in the drawing) perpendicular to the first substrate 210 or the second substrate 110. For example, the second thickness T2 of the non-stacked region NS may be a maximum thickness of the non-stacked region NS.

In implementations, a pad region 200P of one semiconductor device 10 may be a portion bonded to another pad region 200P of another semiconductor device 10 for electrically and physically connecting a plurality of semiconductor devices 10. The pad region 200P may be referred to as a connecting region or a bonding region. The pad region 200P may be a region defined by imaginary lines connecting outer edges of a plurality of through connecting portions 280 included in the pad region 200P in a plan view.

The pad region 200P may include a through connecting portion 280 including a through portion 284 or a first portion that passes through at least a partial portion of the circuit region 200. In this instance, at least a partial portion of a through connecting portion 280 (e.g., a bonding structure 282 or the through portion 284) may be electrically connected to the wiring layer 236 of the circuit region 200.

In implementations, the through connecting portion 280 may include the bonding structure 282 at the first surface 201 of the circuit region 200, the through portion 284 passing through at least a partial portion of the circuit region 200 to connect the bonding structure 282 and a second surface 202 of the circuit region 200. The through connecting portion 280 may further include a pad 286 connected to the through portion 284 at the second surface 202 of the circuit region 200. In this instance, the first surface 201 of the circuit region 200 may be a surface facing the cell region 100 or be a surface (an upper surface in FIG. 2) where the first bonding structure 290 is positioned. The second surface 202 of the circuit region 200 may be a surface opposite to the first surface 201 of the circuit region 200 or be an outer surface.

In implementations, the bonding structure 282 may be a kind of a bonding pad. The bonding structure 282 may be formed by the same process as the first bonding structure 290 and may include the same material as the first bonding structure 290 and may be at the same layer as the first bonding structure 290. A peripheral area of the first bonding structure 290 and the bonding structure 282 at the first surface 201 of the circuit region 200 may be covered by the first bonding insulation layer 292. According to this, a separate process for manufacturing the bonding structure 282 is not needed.

However, the implementations are not limited thereto. In some implementations, the bonding structure 282 may be formed by a different process from the first bonding structure 290, may include a different material from the first bonding structure 290, or may be at a different layer from the first bonding structure 290. In a peripheral area of the bonding structure 282, an insulation layer different from the first bonding insulation layer 292 may be positioned.

The through portion 284 may pass through at least a partial portion of the first substrate 210 to electrically connect the bonding structure 282 and the pad 286. For example, the through portion 284 may include a through silicon via (TSV). The through portion 284 may be electrically insulated from the first substrate 210 by an insulation portion 210a.

The pad 286 connected to the through portion 284 at the second surface 202 of the circuit region 200 may be a kind of a bonding pad. In a peripheral area of the pad 286, an insulation layer may be included or might not be included. Various modifications are possible. For example, the pad 286 might not be at the second surface 202 of the circuit region 200.

For example, the bonding structure 282, the through portion 284, or the pad 286 may include at least one of copper, aluminum, tungsten, nickel, gold, tin, manganese, cobalt, titanium, tantalum, ruthenium, or beryllium, or an alloy including the same

In implementations, an interconnection member 288 may be on the pad 286. The interconnection member 288 may have a shape of a land, a ball, a pin, or a bump. For example, the interconnection member 288 may include a fine bump including a solder material, but the implementations are not limited thereto. The interconnection member 288 may include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, the interconnection member 288 may include tin, or may include an alloy including tin (e.g., a Sn—Ag based alloy, more particularly, a Sn—Ag alloy or a Sn—Ag based alloy further including copper or so on).

In a plan view, the through connecting portions 280 may be spaced apart from each other at a regular interval to form a plurality of rows and a plurality of columns in the pad region 200P. However, the implementations are not limited thereto. The plurality of through connecting portions 280 may be positioned to form one row or one column in the pad region 200P. Further, a number, an arrangement, or so on of the through connecting portion 280 may be variously modified.

In implementations, the non-stacked region NS may be at one edge in one direction but might not be at the other edge in the one direction in a plan view. For example, the non-stacked region NS may be at one edge in a first direction (the X-axis direction in FIG. 1) but might not be at the other edge in the first direction.

More particularly, in a plan view, the non-stacked region NS may be at a side of one edge (a lower edge in FIG. 1) in the first direction (the X-axis direction in FIG. 1) and extend in a second direction (the Y-axis direction in FIG. 1) that is transverse to (e.g., perpendicular to) the first direction in a plan view. In a plan view, the non-stacked region NS may be at a side of one edge in a short axis direction of the semiconductor device 10 and extend in a long axis direction of the semiconductor device 10.

In a plan view, the stacked region SS may be at a side of the other edge (an upper edge in FIG. 1) in the first direction (the X-axis direction in FIG. 1) and extend in the second direction (the Y-axis direction in the drawing). In a plan view, the stacked region SS may be at a side of the other edge in the short axis direction of the semiconductor device 10 and extend in the long axis direction of the semiconductor device 10.

When the non-stacked region NS is at the side of the one edge in the first direction and extends in the second direction as in the above, the pad region 200P may be at the side of the one edge in the first direction and extend in the second direction. For example, a ratio of a width of the pad region 200P to a width of non-stacked region NS may be 50% or more (e.g., 80% or more) in the first direction, and a ratio of a length of the pad region 200P to a length of non-stacked region NS may be 50% or more (e.g., 80% or more) in the second direction. Thereby, an area of the pad region 200P may be secured. Accordingly, a number of the plurality of through connecting portions 280 may be sufficiently secured, and the plurality of semiconductor devices 10 may be stably electrically connected to each other through the pad region 200P. Further, the area of the pad region 200P, which is a bonding region, may be secured, thereby enhancing structural stability in a bonding of the plurality of semiconductor devices 10.

In implementations, the semiconductor device 10 may have an asymmetrical shape in the first direction. That is, the stacked region SS including the cell region 100 and the circuit region 200 may be in a part of the first direction, and the non-stacked region NS including the pad region 200P may be in another part of the first direction. A step where a thickness of the semiconductor device 10 is changed may be provided at a boundary between the stacked region SS and the non-stacked region NS in the first direction.

In a portion where the stacked region SS is positioned, the semiconductor device 10 may have a symmetrical shape in the second direction since the stacked region SS is in an entire region of the second direction while the non-stacked region NS is not positioned there. In a portion where the non-stacked region NS is positioned, the semiconductor device 10 may have a symmetrical shape in the second direction since the non-stacked region NS is in an entire region of the second direction while the stacked region SS is not positioned there.

For example, in a plan view, a width W of the non-stacked region NS in the first direction (the X-axis direction in the drawing) may be less than a length L of the non-stacked region NS in the second direction (the Y-axis direction in the drawing). In a plan view, a width of the pad region 200P in the first direction may be less than a length of the pad region 200P in the second direction.

In implementations, in a plan view, the width W of the non-stacked region NS or the width of the pad region 200P in the first direction may be less than a width W1 of the stacked region SS or a width of the cell region 100 in the first direction. Accordingly, in a plan view, an area of the non-stacked region NS or an area of the pad region 200P may be less than an area of the stacked region SS or an area of the cell region 100. Thereby, the area of the stacked region SS or the area of the cell region 100 may be sufficiently secured. An area of a connecting region (e.g., the pad region 200P) of a first semiconductor device for a connection with a second semiconductor device may be less than an area of a non-overlapping region (e.g., the stacked region SS) of the first semiconductor device that does not overlap the second semiconductor device.

In implementations, the first direction or the short axis direction is parallel to the transverse direction that is transverse to the extension direction of the gate electrode 130. Accordingly, the stacked region SS or the non-stacked region NS extend in the extension direction of the gate electrode 130, but the implementations are not limited thereto. In some implementations, the first direction or the short axis direction may be parallel to the extension direction of the gate electrode 130, or the stacked region SS or the non-stacked region NS may extend the transverse direction that is transverse to the extension direction of the gate electrode 130. Various other modifications are possible.

In implementations, in a plan view, the logic circuit 200L, the decoder circuit 200D, and the page buffer 200B may overlap at least a partial portion of the stacked region SS. FIG. 1, it is illustrated as an example that the page buffer 200B is at a side of one side (a left side in FIG. 1) in the second direction (the Y-axis direction in FIG. 1) and one side (a lower side in FIG. 1) in the first direction (the X-axis direction in FIG. 1), the logic circuit 200L is at a side of the one side (the left side in FIG. 1) in the second direction and the other side (an upper side in FIG. 1) in the first direction, and the decoder circuit 200D is at a side of the other side (a right side in FIG. 1) in the second direction.

For example, the cell array region 102 may be at a side of the one side (the left side in FIG. 1) in the second direction (the Y-axis direction in FIG. 1) and the connection region 104 may be at a side of the other side (the right side in FIG. 1) in the second direction. In a plan view, the decoder circuit 200D may overlap at least a partial portion of the connection region 104.

However, the implementations are not limited thereto. An arrangement of the decoder circuit 200D, the logic circuit 200L, and the page buffer 200B, or an arrangement of the cell array region 102 and the connection region 104 may be variously modified.

In implementations, the semiconductor device 10 may be a bonding semiconductor device bonded by a chip-to-chip (C2C) bonding process or a chip-on-wafer bonding process using hybrid bonding the circuit region 200 and the cell region 100.

For example, in the chip-to-chip bonding process, a first chip (e.g., a lower chip) including the circuit region 200 may be manufactured, a second chip (e.g., an upper chip) including the cell region 100 may be manufactured, and the first chip and the second chip may be bonded. For example, in the chip-on-wafer bonding process, a second chip (e.g., an upper chip) including the cell region 100 may be bonded to a preliminary circuit region including a plurality of first chips (e.g., lower chips), each including the circuit region 200, and the bonded structure may be cut into a plurality of individual semiconductor devices to manufacture the semiconductor device 10.

In implementations, in a plan view, a size or an area of the circuit region 200 and a size or an area of the cell region 100 are different from each other, at least one of the circuit region 200 and the cell region 100 may be manufactured to have a chip type, and then, a bonding process may be performed. Thereby, the circuit region 200 and the cell region 100 having different sizes or areas in a plan view may be easily bonded to each other. In this instance, by the chip-on-wafer bonding process, the semiconductor device 10 may be formed by an easier process using the preliminary circuit region including the plurality of circuit regions 200.

The bonding semiconductor device according to implementations may be or include a bonding memory device, for example, a bonding vertical NAND (BV-NAND) flash memory. However, the implementations are not limited thereto. The bonding semiconductor device may be or include any of various semiconductor devices, semiconductor elements, semiconductor packages, or so on.

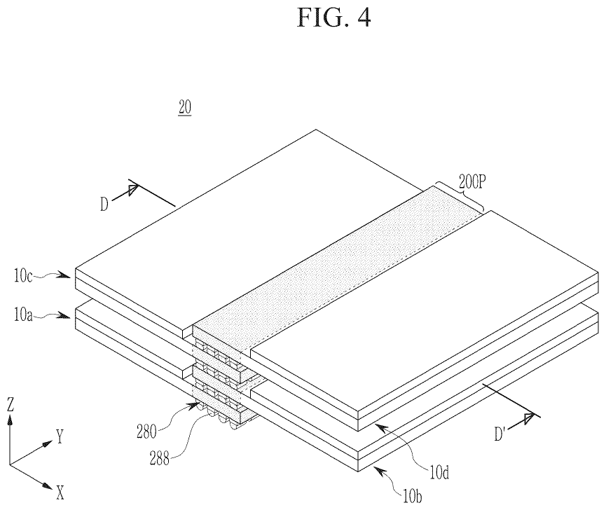

In implementations, the semiconductor device 10 includes the non-stacked region NS having a relatively small second thickness T2. A plurality of semiconductor devices 10 may be bonded to each other using the pad region 200P in the non-stacked region NS to form a semiconductor package 20. An implementation and a modified implementation of a semiconductor package 20 including the semiconductor device 10 will be described in detail with reference to FIG. 4 to FIG. 7.

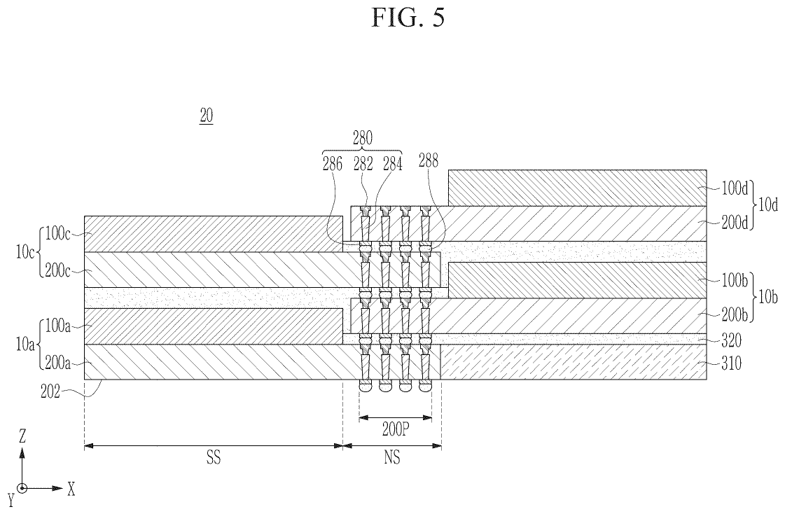

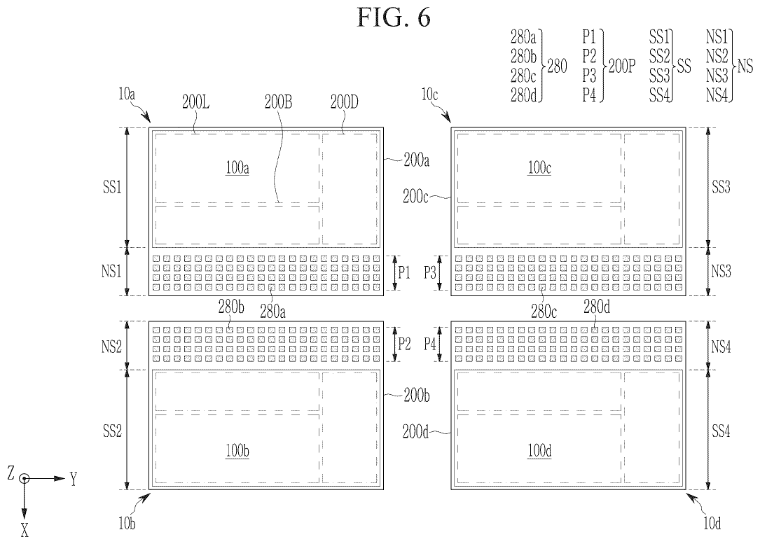

FIG. 4 is a perspective view schematically illustrating a semiconductor package 20 according to implementations. FIG. 5 is a cross-sectional view illustrating the semiconductor package 20 taken along line D-D′ in FIG. 4. FIG. 6 is a development view illustrating a plurality of semiconductor devices 10a, 10b, 10c, and 10d included in the semiconductor package 20 illustrated in FIG. 4 to have a gap therebetween.

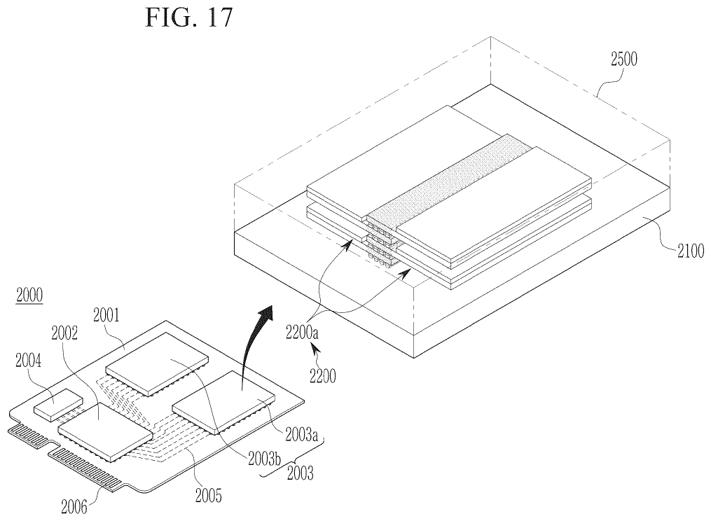

For simple illustration and a clear understanding, in FIG. 4 to FIG. 7 and the below description, a stacking structure 2200 (refer to FIG. 17) for a package is mainly illustrated and described. The stacking structure 2200 for the package includes a plurality of semiconductor devices 10a, 10b, 10c, and 10d included in the semiconductor package 20, a boding layer 320 for boding the plurality of semiconductor devices 10a, 10b, 10c, and 10d, or so on. The stacking structure 2200 for the package may be a portion disposed on or bonded to a package substrate 2100 (refer to FIG. 17) and molded by a molding layer 2500 (refer to FIG. 17). For simple illustration and a clear understanding, in FIG. 4, the pad portion 200P is schematically illustrated and the base member 310 and the bonding layer 320 is omitted.

Referring to FIG. 4 to FIG. 6, in implementations, a semiconductor package 20 may include a plurality of semiconductor devices 10a, 10b, 10c, and 10d. More particularly, the plurality of semiconductor devices 10a, 10b, 10c, and 10d may include a first semiconductor device 10a, and a second semiconductor device 10b connected to the first semiconductor device 10a. The plurality of semiconductor devices 10a, 10b, 10c, and 10d may further include a third semiconductor device 10c connected to the second semiconductor device 10b, and a fourth semiconductor device 10d connected to the third semiconductor device 10c. In FIG. 4 to FIG. 6, it is illustrated as an example that the plurality of semiconductor devices 10a, 10b, 10c, and 10d may include four semiconductor devices sequentially stacked (that is, the first semiconductor device 10a, the second semiconductor device 10b, the third semiconductor device 10c, and the fourth semiconductor device 10d), but the implementations are not limited thereto. Therefore, a number of the plurality of semiconductor devices 10a, 10b, 10c, and 10d included in the semiconductor package 20 may be two, three, or five or more.

The first semiconductor device 10a may include a first stacked region SS1 where a first cell region 100a including a first memory cell structure is on a first circuit region 200a and a first non-stacked region NS1 where a first pad region P1 is positioned outside the first stacked region SS1. Unless otherwise described, the description of the circuit region 200, the cell region 100, the pad region 200P, the stacked region SS, and the non-stacked region NS with reference to FIG. 1 to FIG. 3 may be applied as it is to the first circuit region 200a, the first cell region 100a, the first pad region P1, the first stacked region SS1, and the first non-stacked region NS1.

The second semiconductor device 10b may include a second stacked region SS2 where a second cell region 100b including a second memory cell structure is on a second circuit region 200b and a second non-stacked region NS2 where a second pad region P2 is positioned outside the second stacked region SS2. Unless otherwise described, the description of the circuit region 200, the cell region 100, the pad region 200P, the stacked region SS, and the non-stacked region NS with reference to FIG. 1 to FIG. 3 may be applied as it is to the second circuit region 200b, the second cell region 100b, the second pad region P2, the second stacked region SS2, and the second non-stacked region NS2.

The third semiconductor device 10c may include a third stacked region SS3 where a third cell region 100c including a third memory cell structure is on a third circuit region 200c and a third non-stacked region NS3 where a third pad region P3 is positioned outside the third stacked region SS3. Unless otherwise described, the description of the circuit region 200, the cell region 100, the pad region 200P, the stacked region SS, and the non-stacked region NS with reference to FIG. 1 to FIG. 3 may be applied as it is to the third circuit region 200c, the third cell region 100c, the third pad region P3, the third stacked region SS3, and the third non-stacked region NS3.

The fourth semiconductor device 10d may include a fourth stacked region SS4 where a fourth cell region 100d including a fourth memory cell structure is on a fourth circuit region 200d and a fourth non-stacked region NS4 where a fourth pad region P4 is positioned outside the fourth stacked region SS4. Unless otherwise described, the description of the circuit region 200, the cell region 100, the pad region 200P, the stacked region SS, and the non-stacked region NS with reference to FIG. 1 to FIG. 3 may be applied as it is to the fourth circuit region 200d, the fourth cell region 100d, the fourth pad region P4, the fourth stacked region SS4, and the fourth non-stacked region NS4.

A connection structure of the first semiconductor device 10a and the second semiconductor device 10b stacked on and connected to the first semiconductor device 10a will be described. The second non-stacked region NS2 of the second semiconductor device 10b may be on the first non-stacked region NS1 of the first semiconductor device 10a to connect the first semiconductor device 10a and the second semiconductor device 10b.

In this instance, in a plan view, in the first semiconductor device 10a, the first pad region P1 may be in a first edge portion adjacent to one side (a lower side in FIG. 6) in the first direction (the X-axis direction in the drawing). In a plan view, in the second semiconductor device 10b, the second pad region P2 may be in a second edge portion adjacent to the other side (an upper side in FIG. 6) in the first direction (the X-axis direction in the drawing). For example, in a state that the second pad region P2 of the second semiconductor device 10b is on the first pad region P1 of the first semiconductor device 10a, the first pad region P1 and the second pad region P2 may be electrically connected to and physically bonded to each other.

In the thickness direction of the semiconductor device 10 (the Z-axis direction in the drawing), the first semiconductor device 10a and the second semiconductor device 10b may be at the same position. The first semiconductor device 10a and the second semiconductor device 10b may be on the same plane. For example, in the thickness direction of the semiconductor device 10 (the Z-axis direction in the drawing), at least a partial portion of the first cell region 100a in the first semiconductor device 10a and at least a partial portion of the second circuit region 200b in the second semiconductor device 10b may be at the same position. For example, at least a partial portion of the first cell region 100a in the first semiconductor device 10a and at least a partial portion of the second circuit region 200b in the second semiconductor device 10b may be one the same plane.

In a cross-sectional view, in the thickness direction of the semiconductor package 20 (the Z-axis direction in the drawing), a distance between the first circuit region 200a (more particularly, the first pad region P1) and the second circuit region 200b (more particularly, the second pad region P2) may be less than a thickness of the first cell region 100a. Unlike the implementation, in the conventional art, a first cell region is between a first circuit region and a second circuit region, and a distance between the first circuit region and the second circuit region is the same or greater than a thickness of the first cell region.

A first through connecting portion 280a of the first semiconductor device 10a and a second through connecting portion 280b of the second semiconductor device 10b may be at the same position or an overlapping position in a plan view. In a plan view, the first through connecting portion 280a of the first semiconductor device 10a and the second through connecting portion 280b of the second semiconductor device 10b at the same position or the overlapping position in a plan view may be electrically connect to each other. For example, in a state that the second pad region P2 of the second semiconductor device 10b is on the first pad region P1 of the first semiconductor device 10a, the first through connecting portion 280a of the first semiconductor device 10a and the second through connecting portion 280b of the second semiconductor device 10b at the overlapping position in a plan view may be electrically connect to each other.

For example, a bonding structure 282 of the first semiconductor device 10a (e.g., a first bonding structure included in the first through connecting portion 280a) and a pad 286 of the second semiconductor device 10b (e.g., a second pad included in the second through connecting portion 280b) may be connected to each other by an interconnection member 288 (e.g., a second interconnection member between the first and second semiconductor devices 10a and 10b). A bonding layer 320 (e.g., a first bonding layer) may surround the interconnection member 288 between the first semiconductor device 10a and the second semiconductor device 10b.

In implementations, a base member 310 may be provided at a lower portion of the second semiconductor device 10b to be positioned at the same layer as at least a partial portion of the first semiconductor device 10a, and the bonding layer 320 may occupy an entire portion of a space between an upper portion of the first semiconductor device 10a and the base member 310 and a lower portion of the second semiconductor device 10b. For example, the bonding layer 320 of a cured film or a paste may be positioned in the space between the upper portion of the first semiconductor device 10a and the base member 310 and the lower portion of the second semiconductor device 10b, and then, the bonding layer 320, the first semiconductor device 10a, the base member 310, and the second semiconductor device 10b may be bonded by thermo-compression bonding. Thereby, the bonding structure 282 of the first semiconductor device 10a and the pad 286 of the second semiconductor device 10b may be electrically connected to each other by the interconnection member 288, and the bonding layer 320 may surround the interconnection member 288 to fill a space between the first semiconductor device 10a and the second semiconductor device 10b.

When the base member 310 is at the lower portion of the second semiconductor device 10b, structural stability in the bonding of the first semiconductor device 10a and the second semiconductor device 10b may be enhanced.

The base member 310 may structurally support the second semiconductor device 10b and may act as a heat dissipation member by including a heat dissipation material to enhance a heat dissipation property. For example, a thermal conductivity of the base member 310 may be greater than a thermal conductivity of the first substrate 210 (refer to FIG. 3) included in the first or second semiconductor device 10a or 10b. The base member 310 may include any of various materials such as metal, resin, or so on. However, implementations are not limited thereto. The thermal conductivity of the base member 310 may be the same as or less than the thermal conductivity of the first substrate 210 (refer to FIG. 3) included in the first or second semiconductor device 10a or 10b. The base member 310 may include any of other various materials.

The bonding layer 320 may include any of various insulating materials (e.g., an adhesive material) capable of boding the first semiconductor device 10a, the base member 310, and the second semiconductor device 10b therebetween. For example, the bonding layer 320 may include or be formed of a die attach film (DAF) or a non-conductive film (NCF). However, the implementations are not limited thereto. The bonding layer 320 may include any of various materials, shapes, or types.

In FIG. 5, it is illustrated that a side surface of the base member 310 is in contact with a side surface of the first circuit region 200a, is in its entirety below the second semiconductor device 10b, and has the same lower surface as the second surface 202 of the first substrate 210 included in the first circuit region 200a. In an example, an insulating material for electrically insulating the base member 310 and the first circuit region 200a may be at the side surface of the base member 310 and/or the side surface of the first circuit region 200a. Thereby, structural stability and heat dissipation may be enhanced by the base member 310. However, implementations are not limited thereto. In some implementations, the side surface of the base member 310 may be spaced apart from the side surface of the first circuit region 200a or may be partially disposed at the lower portion of the second semiconductor device 10b. The lower surface of the base member 310 may be higher or lower than the second surface 202 of the first substrate 210 included in the first circuit region 200a. In some implementations, the base member 310 might be not provided.

In FIG. 4, it is illustrated that an interconnection member 288 (e.g., a first interconnection member) is at a lower portion of the first semiconductor device 10a, but the implementations are not limited thereto. The first semiconductor device 10a is the lowermost semiconductor device of the semiconductor package 20 connected or bonded to the package substrate 2100. Accordingly, the first interconnection member at the lower portion of the first semiconductor device 10a may have a different material, a different shape, or a different arrangement from the interconnection member 288 (e.g., the second interconnection member) between the first semiconductor device 10a and the second semiconductor device 10b, an interconnection member 288 (e.g., a third interconnection member) between the second semiconductor device 10b and the third semiconductor device 10c, or an interconnection member 288 (e.g., a fourth interconnection member) between the third semiconductor device 10c and the fourth semiconductor device 10d. In some implementations, the first interconnection member at the lower portion of the first semiconductor device 10a might not be provided, and the package substrate 2100 and the first semiconductor device 10a may be electrically connected to each other by an interconnection member or so on included in the package substrate 2100. However, the implementations are not limited thereto. For example, the first interconnection member may have the same material, shape, or arrangement as at least one of the first to third interconnection members. Other various modifications are possible.

In a plan view, the first semiconductor device 10a and the second semiconductor device 10b may have a symmetrical shape based on the pad region 200P (e.g., the first pad region P1 or the second pad region P2). In FIG. 6, it is illustrated as an example that the first circuit region 200a of the first semiconductor device 10a and the second circuit region 200b of the second semiconductor device 10b may have a symmetrical shape based on the pad region 200P in the first direction (the X-axis direction in the drawing) where the stacked region SS and the non-stacked region NS positioned in a plan view. For example, in a plan view, the logic circuit 200L, the decoder circuit 200D, and the page buffer 200B of the first circuit region 200a may have a symmetrical shape with the logic circuit 200L, the decoder circuit 200D, and the page buffer 200B of the second circuit region 200b based on the pad region 200P in the first direction. In some implementations, in a plan view, a cell array region 102 (refer to FIG. 3) and a connection region 104 (refer to FIG. 3) of the first cell region 100a may have a symmetrical shape with the cell array region 102 and the connection region 104 of the second cell region 100b based on the pad region 200P in the first direction. However, the implementations are not limited thereto.

In a plan view, in the third semiconductor device 10c, the third pad region P3 may be in the first edge portion adjacent to the one side (the lower side in FIG. 6) in the first direction (the X-axis direction in the drawing). For example, in a state that the third pad region P3 of the third semiconductor device 10c is on the second pad region P2 of the second semiconductor device 10b, the second pad region P2 and the third pad region P3 may be electrically connected to and physically bonded to each other.

In a plan view, the second through connecting portion 280b of the second semiconductor device 10b and the third through connecting portion 280c of the third semiconductor device 10c at the same position or the overlapping position in a plan view may be electrically connected to each other. For example, a bonding structure 282 of the second semiconductor device 10b (e.g., a second bonding structure included in the second through connecting portion 280b) and a pad 286 of the third semiconductor device 10c (e.g., a third pad included in the third through connecting portion 280c) may be connected to each other by an interconnection member 288 (e.g., a third interconnection member between the second and third semiconductor devices 10b and 10c). A bonding layer 320 (e.g., a second bonding layer) may surround the interconnection member 288 between the second semiconductor device 10b and the third semiconductor device 10c.

In this instance, the bonding layer 320 may occupy the entirety of a space between an upper portion of the first semiconductor device 10a and the second semiconductor device 10b and a lower portion of the third semiconductor device 10c. In this instance, in the thickness direction of the semiconductor device 10 (the Z-axis direction in the drawing), a partial portion (e.g., the first cell region 100a) of the first semiconductor device 10a at the same position as the second semiconductor device 10b may act as a kind of a base member. Thereby, structural stability in the bonding of the second semiconductor device 10b and the third semiconductor device 10c may be enhanced.

Unless otherwise described, an arrangement and a connection structure of the first semiconductor device 10a and the second semiconductor device 10b may be applied to an arrangement and a connection structure of the second semiconductor device 10b and the third semiconductor device 10c as it is.

In a plan view, in the fourth semiconductor device 10d, the fourth pad region P4 may be in the second edge portion adjacent to the other side (the upper side in FIG. 6) in the first direction (the X-axis direction in the drawing). In a state that the fourth pad region P4 of the fourth semiconductor device 10d is on the third pad region P3 of the third semiconductor device 10c, the third pad region P3 and the fourth pad region P4 may be electrically connected to and physically bonded to each other.

In a plan view, the third through connecting portion 280c of the third semiconductor device 10c and the fourth through connecting portion 280d of the fourth semiconductor device 10d at the same position or the overlapping position in a plan view may be electrically connected to each other. For example, a bonding structure 282 of the third semiconductor device 10c (e.g., a third bonding structure included in the third through connecting portion 280c) and a pad 286 of the fourth semiconductor device 10d (e.g., a fourth pad included in the fourth through connecting portion 280d) may be connected to each other by an interconnection member 288 (e.g., a fourth interconnection member between the third and fourth semiconductor devices 10c and 10d). A bonding layer 320 (e.g., a third bonding layer) may surround the interconnection member 288 between the third semiconductor device 10c and the fourth semiconductor device 10d.

In this instance, the bonding layer 320 may occupy the entirety of a space between an upper portion of the third semiconductor device 10c and the second semiconductor device 10b and a lower portion of the fourth semiconductor device 10d. In this instance, in the thickness direction of the semiconductor device 10 (the Z-axis direction in the drawing), a partial portion (e.g., the second cell region 100b) of the second semiconductor device 10b at the same position as the third semiconductor device 10c may act as a kind of a base member. Thereby, structural stability in the bonding of the third semiconductor device 10c and the fourth semiconductor device 10d may be enhanced.

Unless otherwise described, an arrangement and a connection structure of the first semiconductor device 10a and the second semiconductor device 10b may be applied to an arrangement and a connection structure of the third semiconductor device 10c and the fourth semiconductor device 10d as it is.

In implementations, the first and second edge portions of the plurality of semiconductor devices 10a, 10b, 10c, and 10d at the one side or the other side in the first direction (the X-axis direction in the drawing) may be alternatively stacked each other to manufacture the semiconductor package 20.

In implementations, the fourth through connecting portion 280d of the uppermost semiconductor device (e.g., the fourth semiconductor device 10d) of the semiconductor package 20 includes the bonding structure 282 (e.g., a fourth bonding structure) and a through portion 284 (e.g., a fourth through portion) in addition to the pad 286 (e.g., the fourth pad). Thereby, the fourth semiconductor device 10d has the same structure as at least one of the first, second, or third semiconductor devices 10a, 10b, or 10c. An additional process for manufacturing a distinct fourth semiconductor device 10d is not needed. Accordingly, a manufacturing process may be made easier. In the drawing, it is illustrated as an example that the fourth bonding structure does not include a structure connected to another portion. In a modified implementation, a connection structure such as a wire may be connected to the fourth bonding structure.

However, the implementations are not limited thereto. The uppermost semiconductor device (e.g., the fourth semiconductor device 10d) of the semiconductor package 20 might not include the bonding structure 282 and the through portion 284.

In FIG. 6, it is illustrated as an example that the third and fourth semiconductor devices 10c and 10d have the same arrangement as the first and second semiconductor devices 10a and 10b. That is, in a plan view, the first circuit region 200a of the first semiconductor device 10a may have the same arrangement as the third circuit region 200c of the third semiconductor device 10c. In a plan view, the second circuit region 200b of the second semiconductor device 10b may have the same arrangement as the fourth circuit region 200d of the fourth semiconductor device 10d.

Accordingly, in a plan view, in the first and third semiconductor device 10a and 10c that are at the same position, the logic circuit 200L, the decoder circuit 200D, and the page buffer 200B of the first semiconductor device 10a may be at the same position as or the corresponding position to the logic circuit 200L, the decoder circuit 200D, and the page buffer 200B of the third semiconductor device 10c. In a plan view, in the first and third semiconductor device 10a and 10c that are at the same position, the cell array region 102 and the connection region 104 of the first semiconductor device 10a may be at the same position as or the corresponding position to the cell array region 102 and the connection region 104 of the third semiconductor device 10c.

In a plan view, in the second and fourth semiconductor device 10b and 10d that are at the same position, the logic circuit 200L, the decoder circuit 200D, and the page buffer 200B of the second semiconductor device 10b may be at the same position as or the corresponding position to the logic circuit 200L, the decoder circuit 200D, and the page buffer 200B of the fourth semiconductor device 10d. In a plan view, in the second and fourth semiconductor device 10b and 10d that are at the same position, the cell array region 102 and the connection region 104 of the second semiconductor device 10b may be at the same position as or the corresponding position to the cell array region 102 and the connection region 104 of the fourth semiconductor device 10d.

Thereby, a pair of semiconductor devices 10 (e.g., the first semiconductor device 10a and the second semiconductor device 10b) and another pair of semiconductor devices 10 (e.g., the third semiconductor device 10c and the fourth semiconductor device 10d) may have the same structure. Thus, a process stacking the plurality of semiconductor devices 10 may be easy.

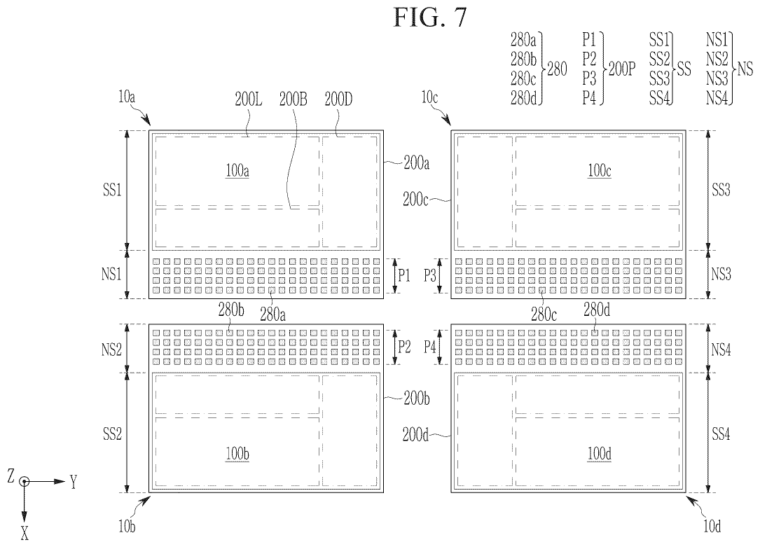

In a modified implementation, as shown in FIG. 7, third and fourth semiconductor devices 10c and 10d may have a symmetrical shape with first and second semiconductor devices 10a and 10b in a second direction (an Y-axis direction in the drawing).

Accordingly, in a plan view, in first and third semiconductor devices 10a and 10c that are at the same position, a logic circuit 200L, a decoder circuit 200D, and a page buffer 200B of the first semiconductor device 10a may have a symmetrical shape with a logic circuit 200L, a decoder circuit 200D, and a page buffer 200B of the third semiconductor device 10c in the second direction. In a plan view, in the first and third semiconductor devices 10a and 10c that are at the same position, a cell array region 102 and a connection region 104 of the first semiconductor device 10a may have a symmetrical shape with a cell array region 102 and a connection region 104 of the third semiconductor device 10c in the second direction.

In a plan view, in the second and fourth semiconductor devices 10b and 10d that are at the same position, the logic circuit 200L, the decoder circuit 200D, and the page buffer 200B of the second semiconductor device 10b may have a mirror symmetrical shape with the logic circuit 200L, the decoder circuit 200D, and the page buffer 200B of the fourth semiconductor device 10d in the second direction. In a plan view, in the second and fourth semiconductor devices 10b and 10d that are at the same position, the cell array region 102 and the connection region 104 of the second semiconductor device 10b may have a mirror symmetrical shape with the cell array region 102 and the connection region 104 of the fourth semiconductor device 10d in the second direction.

Thereby, a pair of semiconductor devices 10 (e.g., the first semiconductor device 10a and the second semiconductor device 10b) and another pair of semiconductor devices 10 (e.g., the third semiconductor device 10c and the fourth semiconductor device 10d) may have a structure rotated 180 degrees in a plan view. Thereby, in a bonding process of the plurality of semiconductor devices 10a, 10b, 10c, and 10d, stability in the first direction and the second direction may be enhanced.

However, the implementations are not limited thereto. An arrangement of the plurality of semiconductor devices 10 in a plan view may be variously modified.

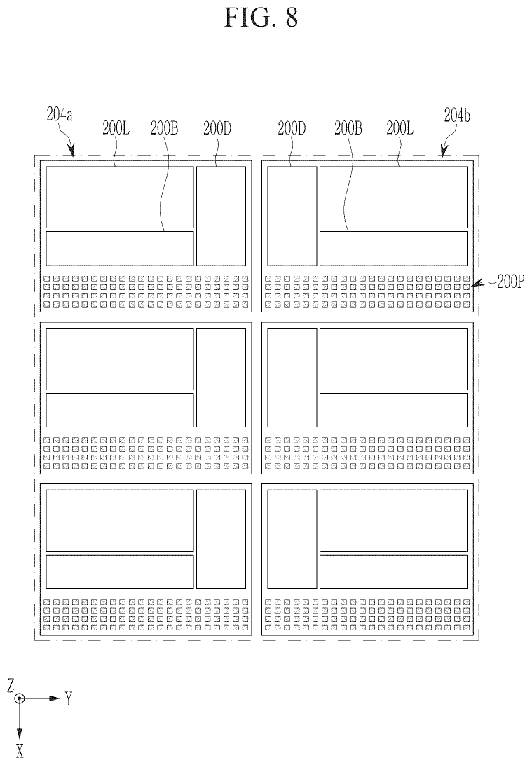

A manufacturing method of a plurality of circuit regions 200a, 200b, 200c, and 200d of the plurality of semiconductor devices 10a, 10b, 10c, and 10d included in the semiconductor package 20 will be described in more detail with reference to FIG. 8 together with FIG. 6 and FIG. 7.

FIG. 8 is a plan view schematically illustrating a process forming a preliminary circuit substrate including a plurality of preliminary circuit regions 204a and 204b corresponding to a plurality of semiconductor devices 10a, 10b, 10c, and 10d included in a semiconductor package 20. The preliminary circuit substrate may include or be a substrate (e.g., a wafer) where the plurality of preliminary circuit regions 204a and 204b corresponding to the plurality of circuit regions 200a, 200b, 200c, and 200d are included in an uncut state.

Referring to FIG. 6 to FIG. 8, a preliminary circuit substrate including a plurality of circuit regions 200a, 200b, 200c, and 200d may include a plurality of preliminary circuit regions 204a and 204b. The plurality of preliminary circuit regions 204a and 204b may include a first preliminary circuit region 204a and a second preliminary circuit region 204b having a symmetrical shape with the first preliminary circuit region 204a in one direction. The first preliminary circuit region 204a and the second preliminary circuit region 204b may be formed to have a symmetrical shape in a process (e.g., a photolithography process) forming the plurality of preliminary circuit regions 204a and 204b.

In FIG. 8, it is illustrated as an example that the first preliminary circuit region 204a and the second preliminary circuit region 204b have the symmetrical shape in the second direction (the Y-axis direction in the drawing), but the implementations are not limited thereto. The first preliminary circuit region 204a and the second preliminary circuit region 204b may have a symmetrical shape in a first direction (an X-axis direction in the drawing). Various other modifications are possible.

In implementations, the first preliminary circuit region 204a may correspond to each of the first circuit region 200a and the third circuit region 200c illustrated in FIG. 6. The second preliminary circuit region 204b may correspond to each of the second circuit region 200b and the fourth circuit region 200d illustrated in FIG. 6. For example, the first preliminary circuit region 204a may correspond to each of the first circuit region 200a and the third circuit region 200c as it is. The second preliminary circuit region 204b may correspond to each of the second circuit region 200b and the fourth circuit region 200d when the second preliminary circuit region 204b rotates 180 degrees in a plan view.

In some implementations, the first preliminary circuit region 204a may correspond to the first circuit region 200a and the fourth circuit region 200d illustrated in FIG. 7. The second preliminary circuit region 204b may correspond to the second circuit region 200b and the third circuit region 200c illustrated in FIG. 7. For example, the first and second preliminary circuit regions 204a and 204b may correspond to the first and third circuit regions 200a and 200c illustrated in FIG. 7, respectively, as it is, and the first and second preliminary circuit regions 204a and 204b may correspond to the fourth and second circuit regions 200d and 200b illustrated in FIG. 7, respectively, when the first and second preliminary circuit regions 204a and 204b are rotated 180 degrees in a plan view.

According to some implementations, the plurality of semiconductor devices 10a, 10b, 10c, and 10d may be connected by using the pad region 200P in the non-stacked region NS having the relatively small thickness to manufacture the semiconductor package 20. Accordingly, a thickness of the semiconductor package 20 in the thickness direction of the semiconductor package 20 (the Z-axis direction in the drawing) may be reduced. More particularly, the thickness of the semiconductor package 20 may be effectively reduced when a number of gate electrodes 130 is increased to increase a data storage capacity of the semiconductor device 10.

In this instance, the plurality of semiconductor devices 10a, 10b, 10c, and 10d may be electrically connected to each other by the through connecting portion 280 included in the pad region 200P, thereby shortening a signal path and reducing a problem such as a signal loss. Accordingly, performance of the semiconductor device 10 or the semiconductor package 20 may be enhanced. A connection structure such as a wire might not be included and thus a process and a structure may be simplified.

In the above description, the plurality of semiconductor devices 10a, 10b, 10c, and 10d are bonded to each other by using the interconnection member 288 and the bonding layer 320. However, the implementations are not limited thereto. At least a part of the plurality of semiconductor devices 10a, 10b, 10c, and 10d may be connected to each other by hybrid bonding or contact bonding. For example, the bonding structure 282 of one semiconductor device 10 and the pad 286 of another semiconductor device 10 connected to the one semiconductor device 10 are bonded to each other in a state such that the bonding structure 282 and the pad 286 are in contact with each other, thereby forming metal bonding. An insulation layer at a periphery of the bonding structure 282 and an insulation layer at a periphery of the pad 286 are bonded to each other in a state such that the insulation layers at the peripheries of the bonding structure 282 and the pad 286 are in contact with each other, thereby forming insulation-layer bonding. Thereby, the interconnection member 288 might not be included and a bonding distance may be minimized. The plurality of the semiconductor devices 10 may be bonded to each other by other various methods.

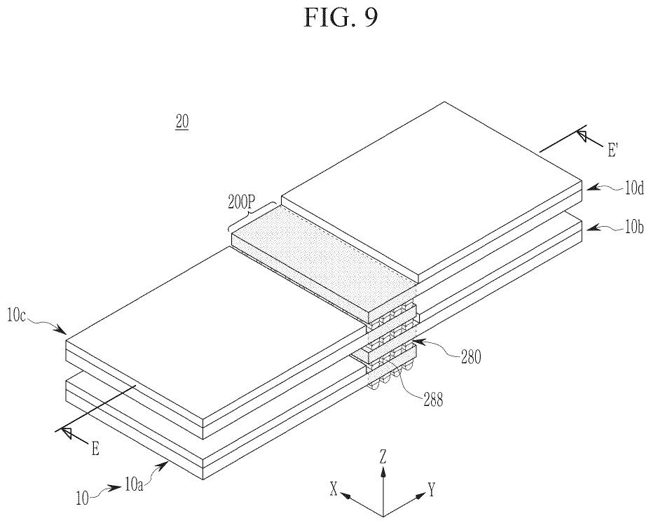

Hereinafter, referring to FIG. 9 to FIG. 15, a semiconductor device 10 and a semiconductor package 20 including the same according to implementations will be described in more detail. To the extent that an element is not described in detail below, it may be understood that the element is at least similar to a corresponding element that has been described elsewhere within the present disclosure. A portion which is not described in the above will be described in detail.

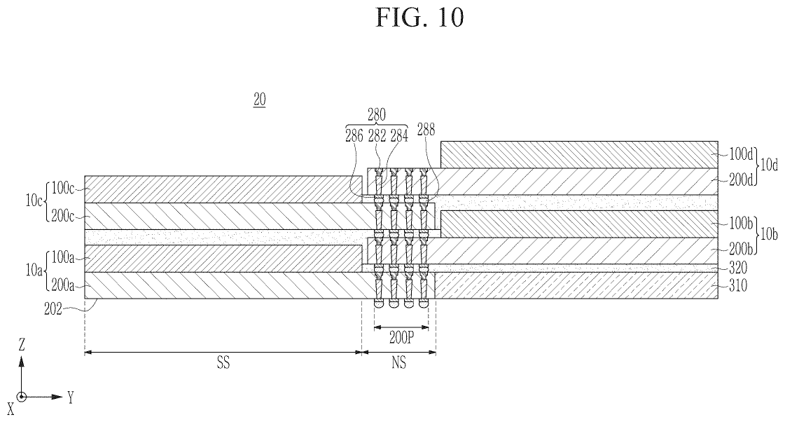

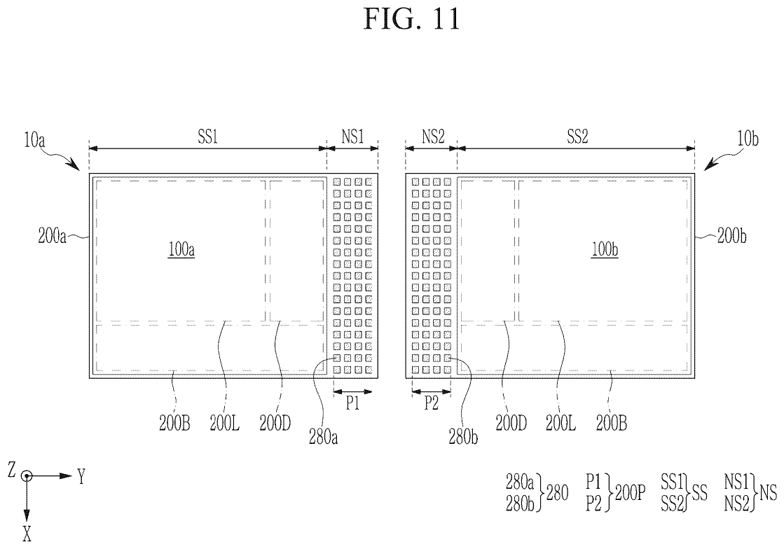

FIG. 9 is a perspective view schematically illustrating a semiconductor device 10 and a semiconductor package 20 including the same according to implementations. FIG. 10 is a cross-sectional view illustrating the semiconductor package 20 taken along line E-E′ in FIG. 9. FIG. 11 is a development view illustrating a plurality of semiconductor devices included in the semiconductor package 20 illustrated in FIG. 9 to have a gap therebetween. For simple illustration, in FIG. 11, first and second semiconductor devices 10a and 10b are mainly illustrated.

Referring to FIG. 9 to FIG. 11, in a semiconductor device 10 according to implementations, a non-stacked region NS may be at one edge in one direction but might not be at the other edge in the one direction in a plan view. For example, the non-stacked region NS may be at one side in a second direction (a Y-axis direction in the drawing) or a long axis direction but might not be at the other edge in the second direction or the long axis direction.

More particularly, in a plan view, the non-stacked region NS may be at a side of one edge (a right or left edge in FIG. 11) in the second direction (the Y-axis direction in FIG. 11) and extend in a first direction (an X-axis direction in FIG. 11) that is transverse to (e.g., perpendicular to) the second direction in a plan view. In a plan view, the non-stacked region NS may be at a side of one edge in the long axis direction of the semiconductor device 10 and extend in a short axis direction of the semiconductor device 10.

In a plan view, the stacked region SS may be at a side of the other edge (a left or right edge in FIG. 11) in the second direction (the Y-axis direction in FIG. 11) and extend in a first direction (the X-axis direction in FIG. 11) in a plan view. In a plan view, the stacked region SS may be at a side of the other edge in the long axis direction of the semiconductor device 10 and extend in the short axis direction of the semiconductor device 10.

When the non-stacked region NS is at the side of the one edge in the second direction and extends in the first direction as in the above, a pad region 200P may be at the side of the one edge in the second direction and extend in the first direction. Thereby, an area of the pad region 200P may be secured.

In implementations, the semiconductor device 10 may have an asymmetrical shape in the second direction. That is, the stacked region SS including the cell region 100 and the circuit region 200 may be in a part of the second direction, and the non-stacked region NS including the pad region 200P may be in another part of the second direction. A step where a thickness of the semiconductor device 10 is changed may be provided at a boundary between the stacked region SS and the non-stacked region NS in the second direction.

In a portion where the stacked region SS is positioned, the semiconductor device 10 may have a symmetrical shape in the first direction since the stacked region SS fills the entire region of the first direction where the non-stacked region NS is not positioned. In a portion where the non-stacked region NS is positioned, the semiconductor device 10 may have a symmetrical shape in the first direction since the non-stacked region NS fills an entire region of the first direction where the stacked region SS is not positioned.

For example, in a plan view, a width of the non-stacked region NS in the second direction (the Y-axis direction in the drawing) may be less than a length of the non-stacked region NS in the first direction (the X-axis direction in the drawing). In a plan view, a width of the pad region 200P in the second direction may be less than a length of the pad region 200P in the first direction.

In implementations, in a plan view, the width of the non-stacked region NS or the width of the pad region 200P in the second direction may be less than a width of the stacked region SS or a width of the cell region 100 in the second direction. Accordingly, in a plan view, an area of the non-stacked region NS or an area of the pad region 200P may be less than an area of the stacked region SS or an area of the cell region 100. Thereby, the area of the stacked region SS or the area of the cell region 100 may be sufficiently secured.

In implementations, the second direction or the long axis direction is parallel to an extension direction of a gate electrode. Accordingly, the stacked region SS or the non-stacked region NS may extend in a transverse direction that is transverse to the extension direction of the gate electrode, but the implementations are not limited thereto. In some implementations, the second direction or the long axis direction may be parallel to the transverse direction that is transverse to the extension direction of the gate electrode, or the stacked region SS or the non-stacked region NS may extend in the extension direction of the gate electrode. Various other modifications are possible.

In implementations, a semiconductor package 20 may include a plurality of semiconductor devices 10a and 10b. More particularly, the plurality of semiconductor devices 10a and 10b may include a first semiconductor device 10a, and a second semiconductor device 10b connected to the first semiconductor device 10a. The plurality of semiconductor devices 10a and 10b may further include a third semiconductor device connected to the second semiconductor device 10b, and a fourth semiconductor device connected to the third semiconductor device.

In this instance, in a plan view, in the first semiconductor device 10a, a first pad region P1 may be in a third edge portion adjacent to one side (a right side in FIG. 11) in the second direction (the Y-axis direction in the drawing). In a plan view, in the second semiconductor device 10b, a second pad region P2 may be in a fourth edge portion adjacent to the other side (a left side in FIG. 11) in the second direction (the Y-axis direction in the drawing). In a plan view, in the third semiconductor device, a third pad region may be in the third edge portion adjacent to the one side in the second direction (the Y-axis direction in the drawing). In a plan view, in the fourth semiconductor device, a fourth pad region may be in the fourth edge portion adjacent to the other side in the second direction (the Y-axis direction in the drawing). In implementations, the third and fourth edge portions of the plurality of semiconductor devices 10a and 10b at the one side or the other side in the second direction (the Y-axis direction in the drawing) may be alternatively stacked each other to manufacture a semiconductor package 20.

In a plan view, the first semiconductor device 10a and the second semiconductor device 10b may have a symmetrical shape based on the pad region 200P (e.g., the first pad region P1 or the second pad region P2). However, the implementations are not limited thereto, and various modifications are possible. Unlike otherwise described, the description of the implementations and the modified implementations with reference to FIG. 4 to FIG. 7 may be applied as it is.

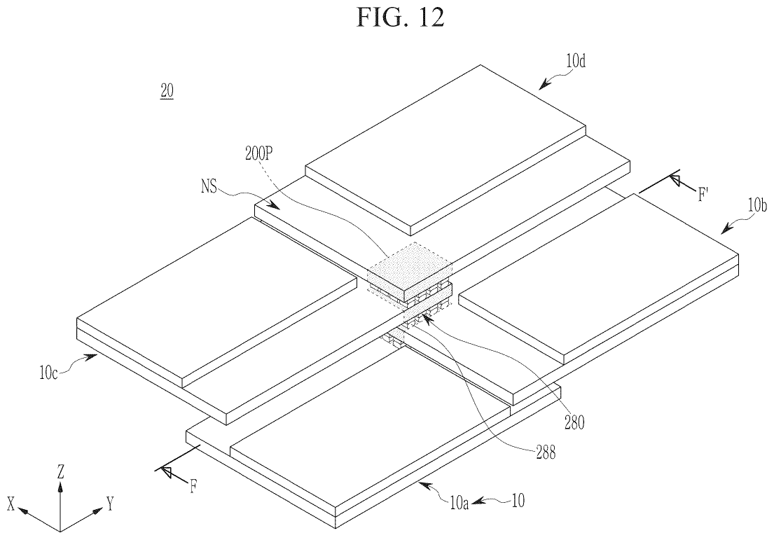

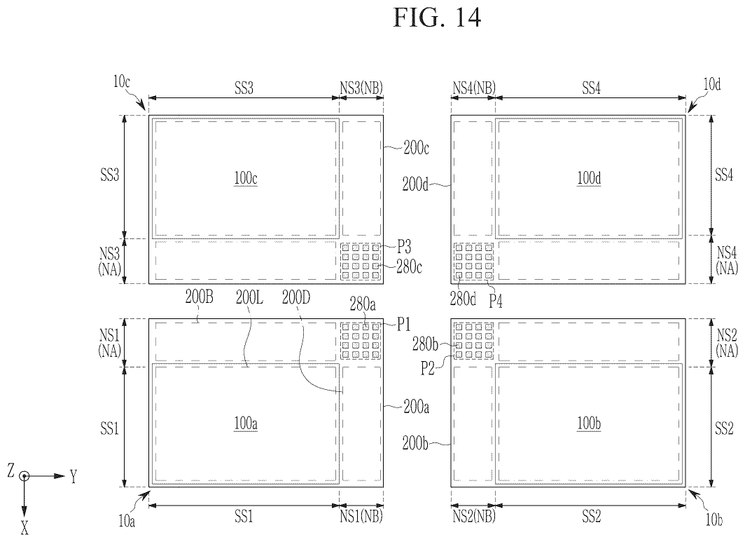

FIG. 12 is a perspective view schematically illustrating a semiconductor device 10 and a semiconductor package 20 including the same according to implementations. FIG. 13 is a cross-sectional view illustrating the semiconductor package 20 taken along line F-F′ in FIG. 12. FIG. 14 is a development view illustrating a plurality of semiconductor devices 10a, 10b, 10c, and 10d included in the semiconductor package 20 illustrated in FIG. 12 to have a gap therebetween.

Referring to FIG. 12 to FIG. 14, in a semiconductor device 10 according to implementations, a non-stacked region NS may include a first region NA and a second region NB. The first region NA may be at a side of one edge (a lower or upper edge in FIG. 14) in a first direction (an X-axis direction in the drawing). The second region NB may be at a side of one edge (a right or left edge) in a second direction (a Y-axis direction in the drawing). In this instance, the non-stacked region NS might not be at a side of the other edge (the upper of lower edge in FIG. 14) in the first direction, and the second region NB might not be at a side of the other edge (the left or right edge) in the second direction.

More particularly, in a plan view, the first region NA may be at a side of one edge (the lower or upper edge in FIG. 14) in the first direction (the X-axis direction in the drawing) and extend in the second direction (the Y-axis direction in the drawing) that is transverse to (e.g., perpendicular to) the first direction in a plan view. In a plan view, the first region NA may be at a side of one edge in a short axis direction of the semiconductor device 10 and extend in a long axis direction of the semiconductor device 10.

In a plan view, the second region NB may be at a side of one edge (a right or left edge in FIG. 14) in the second direction (the Y-axis direction in FIG. 11) and extend in the first direction (the X-axis direction in the drawing) that is transverse to (e.g., perpendicular to) the second direction in a plan view. In a plan view, the second region NB may be at a side of one edge in the long direction of the semiconductor device 10 and extend in the short axis direction of the semiconductor device 10.

In implementations, a pad region 200P may be at a corner portion where the first region NA and the second region NB cross each other in a plan view. The stacked region SS may be at a side of the other edge in the first direction and a side of the other edge in the second direction.

In implementations, the semiconductor device 10 may have an asymmetrical shape in each of the first direction and the second direction. That is, the stacked region SS including the cell region 100 and the circuit region 200 may be in a part in each of the first direction and the second direction, and the non-stacked region NS including the pad region 200P may be in another part in each of the first direction and the second direction. Steps may be provided at boundaries between the stacked region SS and the non-stacked region NS in each of the first direction and the second direction. In the step, a thickness of the semiconductor device 10 is changed.

For example, in a plan view, a width of the first region NA in the first direction (the X-axis direction in the drawing) may be less than a length of the first region NA in the second direction (the Y-axis direction in the drawing). In a plan view, a width of the second region NB in the second direction (the Y-axis direction in the drawing) may be less than a length of the second region NB in the first direction (the X-axis direction in the drawing).

In implementations, in a plan view, a width of the non-stacked region NS or the width of the pad region 200P in the first direction or the second direction may be less than a width of the stacked region SS or a width of the cell region 100 in the first direction or the second direction. For example, in a plan view, an area of the non-stacked region NS or an area of the pad region 200P may be less than an area of the stacked region SS or an area of the cell region 100. Thereby, the area of the stacked region SS or the area of the cell region 100 may be sufficiently secured. In some implementations, in a plan view, the area of the non-stacked region NS may be the same as or greater than the area of the stacked region SS or an area of the cell region 100.

In implementations, in a plan view, a logic circuit 200L may overlap at least a partial portion of the stacked region SS, and a decoder circuit 200D and a page buffer 200B may overlap at least a partial portion of the non-stacked region NS. In FIG. 14, it is illustrated as an example that the logic circuit 200L overlaps at least a partial portion of the stacked region SS, the page buffer 200B overlaps a region other than the pad region 200P in the first region NA, and the decoder circuit 200D overlaps a region other than the pad region 200P in the second region NB. Thereby, areas of the logic circuit 200L, the page buffer 200B, and the decoder circuit 200D included in the circuit region 200 may be sufficiently secured.

For example, the logic circuit 200L may overlap at least a partial portion of a cell array region 102 (refer to FIG. 3), and the decoder circuit 200D may overlap at least a partial portion of a connection region 104 (refer to FIG. 3).

However, the implementations are not limited thereto. An arrangement of the decoder circuit 200D, the logic circuit 200, and the page buffer 200B may be variously modified.

In implementations, a semiconductor package 20 may include a plurality of semiconductor devices 10a, 10b, 10c, and 10d. More particularly, the plurality of semiconductor devices 10a, 10b, 10c, and 10d may include a first semiconductor device 10a, and a second semiconductor device 10b connected to the first semiconductor device 10a. The plurality of semiconductor devices 10a, 10b, 10c, and 10d may further include a third semiconductor device 10c connected to the second semiconductor device 10b, and a fourth semiconductor device 10d connected to the third semiconductor device 10c.

In this instance, in a plan view, in the first semiconductor device 10a, a first pad region P1 may be in a first corner portion adjacent to one side (an upper side in FIG. 14) in the first direction (the X-axis direction in the drawing) and one side (a right side in FIG. 14) in the second direction (the Y-axis direction in the drawing). In a plan view, in the second semiconductor device 10b, a second pad region P1 may be in a second corner portion adjacent to the one side (the upper side in FIG. 14) in the first direction and the other side (a left side in FIG. 14) in the second direction. In a state that the second region NB of the second semiconductor device 10b is on the second region NB of the first semiconductor device 10a, the first pad region P1 and the second pad region P2 may be electrically connected to and physically bonded to each other.

In a plan view, in the third semiconductor device 10c, a third pad region P3 may be in a third corner portion adjacent to the other side (a lower side in FIG. 14) in the first direction (the X-axis direction in the drawing) and the one side (the right side in FIG. 14) in the second direction (the Y-axis direction in the drawing). For example, in a state that the third pad region P3 of the third semiconductor device 10c is on the second pad region P2 of the second semiconductor device 10b, the second pad region P2 and the third pad region P3 may be electrically connected to and physically bonded to each other. For example, a portion of a second non-stacked region NS2 in the second semiconductor device 10b other than the second pad region P2 (e.g., portions of the first region NA and the second region NB other than the second pad region P2) might not overlap a portion of a third non-stacked region NS3 in the third semiconductor device 10c other than the third pad region P3 (e.g., portions of the first region NA and the second region NB other than the third pad region P2).

In a plan view, in the fourth semiconductor device 10d, a fourth pad region P4 may be in a fourth corner portion adjacent to the other side (the lower side in FIG. 14) in the first direction (the X-axis direction in the drawing) and the other side (the left side in FIG. 14) in the second direction (the Y-axis direction in the drawing). In a state that the second region NB of the fourth semiconductor device 10d is on the second region NB of the third semiconductor device 10c, the third pad region P3 and the fourth pad region P4 may be electrically connected to and physically bonded to each other.

However, the implementations are not limited thereto. The fourth semiconductor device 10d may be on the second semiconductor device 10b. That is, in a state that the first region NA of the second semiconductor device 10b and the first region NA of the fourth semiconductor device 10d overlap each other, the second semiconductor device 10b and the fourth semiconductor device 10d may be connected. Subsequently, the third semiconductor device 10c may be on the fourth semiconductor device 10d. That is, in a state that the second region NB of the fourth semiconductor device 10d and the second region NB of the third semiconductor device 10c overlap each other, the fourth semiconductor device 10d and the third semiconductor device 10c may be connected. Accordingly, an overlapping region of two adjacent semiconductor device among the plurality of semiconductor devices 10a, 10b, 10c, and 10d may be relatively sufficiently secured, thereby enhancing structural stability.

In implementations, in a plan view, the first pad region P1, the second pad region P2, the third pad region P3, and the fourth pad region P4 may entirely overlap each other in a corner portion of the first, second, third, or fourth semiconductor device 10a, 10b, 10c, or 10d. However, implementations are not limited thereto. The first to fourth pad regions P1, P2, P3, and P4 may include at least a partial portion that does not overlap another one of the first to fourth pad regions P1, P2, P3, and P4. Various other modifications are possible.

In implementations, a first cell region 100a of the first semiconductor device 10a, a second cell region 100b of the second semiconductor device 10b, a third cell region 100c of the third semiconductor device 10c, and a fourth cell region 100d of the fourth semiconductor device 10d may be positioned not to overlap each other. Accordingly, the first to fourth cell regions 100a, 100b, 100c, and 100d might not affect a bonding or connection of the plurality of semiconductor devices 10a, 10b, 10c, and 10d. Therefore, the above structure may be applied to a case in which a thickness of the first, second, third, or fourth cell region 100a, 100b, 100c, or 100d is larger than a thickness at least one of the first, second, third, or fourth circuit region 200a, 200b, 200c or 200d.

In a plan view, the first semiconductor device 10a and the second semiconductor device 10b may have a symmetrical shape based on the pad region 200P (e.g., the first pad region P1 or the second pad region P2) in the second direction (the Y-axis direction in the drawing). In a plan view, the third semiconductor device 10c and the fourth semiconductor device 10d may have a symmetrical shape based on the pad region 200P (e.g., the third pad region P3 or the fourth pad region P4) in the second direction.

In a plan view, the third semiconductor device 10c may have a symmetrical shape with the first semiconductor device 10a based on the pad region 200P (e.g., the first pad region P1 or the third pad region P3) in the first direction (the X-axis direction in the drawing), and the fourth semiconductor device 10d may have a structure in which the first semiconductor device 10a is rotated 180 degrees. In a plan view, the fourth semiconductor device 10d may have a symmetrical shape with the second semiconductor device 10b based on the pad region 200P (e.g., the second pad region P2 or the fourth pad region P4) in the first direction, and the third semiconductor device 10c may have a structure in which the second semiconductor device 10b is rotated 180 degrees. For example, a pair of semiconductor devices 10 (e.g., the first semiconductor device 10a and the second semiconductor device 10b) may have a structure in which another pair of semiconductor devices 10 (e.g., the third semiconductor device 10c and the fourth semiconductor device 10d) is rotated 180 degrees in a plan view.

However, the implementations are not limited thereto. An arrangement of the plurality of the semiconductor devices 10 in a plan view may be variously modified.

Hereinafter, referring to FIG. 15, a semiconductor device according to implementations will be described in more detail. To the extent that an element is not described in detail below, it may be understood that the element is at least similar to a corresponding element that has been described elsewhere within the present disclosure. Hereinafter, a portion which is not described in the above will be mainly described.

FIG. 15 is a partial cross-sectional view schematically illustrating a semiconductor device 10f according to implementations.

Referring to FIG. 15, in a semiconductor device 10f according to implementations, a cell region 100f including a second substrate 110f may be stacked or disposed on a circuit region 200. For example, the second substrate 110f, a gate stacking structure 120, a channel structure CH, or so on may be formed on the circuit region 200 to manufacture the semiconductor device 10f.

Unless otherwise described, the description of the circuit region 200 referring to FIG. 1 to FIG. 14 may be applied to the circuit region 200. Unless otherwise described, the description of the cell region 100 referring to FIG. 1 to FIG. 14 may be applied to the cell region 100f.

In implementations, the second substrate 110f may include a semiconductor layer including a semiconductor material. For example, the second substrate 110f may be a semiconductor substrate including or formed of a semiconductor material or may be a semiconductor substrate in which a semiconductor layer is on a base substrate. For example, the second substrate 110f may include or be formed of silicon, germanium, silicon-germanium, silicon on insulator, germanium on insulator, or so on. Here, the semiconductor layer included in the second substrate 110f may be doped with a p-type dopant (such as boron (B), gallium (Ga), or so on) or an n-type dopant (such as phosphorus (P), arsenic (As), or so on). However, the implementations are not limited to a material of the second substrate 110f, a conductive type of the dopant doped to the semiconductor layer, or so on.

Horizontal conductive layers 112 and 114 may be provided between the second substrate 110f and the gate stacking structure 120 in the cell array region 102. The horizontal conductive layers 112 and 114 may electrically connect (e.g., directly connect) the channel structure CH and the second substrate 110f. The horizontal conductive layers 112 and 114 may include a first horizontal conductive layer 112 and/or a second horizontal conductive layer 114 sequentially on the second substrate 110f. The first horizontal conductive layer 112 may act as a partial portion of a common source line of the semiconductor device 10f. For example, the first horizontal conductive layer 112 may act as the common source line together with the second substrate 110f.

The first and second horizontal conductive layers 112 and 114 may include a semiconductor material (e.g., polycrystalline silicon). For example, the first horizontal conductive layer 112 may include a polycrystalline silicon layer including a dopant. The implementations are not limited thereto. The second horizontal conductive layer 114 may include a material (e.g., an insulating material) different from a material of the first horizontal conductive layer 112, or the second horizontal conductive layer 114 might not be provided. In this instance, a source contact portion may be connected to the second substrate 110f.

The implementations are not limited thereto, and an electrical connection structure between the channel structure CH and the horizontal conductive layers 112 and 114 and/or the second substrate 110f may be variously modified.

In implementations, the gate stacking structure 120 may be sequentially stacked on an upper portion of the second substrate 110f (e.g., an upper portion of the horizontal conductive layer 112 and 114) in the drawing and may have a structure in which the gate stacking structure 120 illustrated in FIG. 3 is disposed in a vertically inverted manner. The channel structure CH passing through the gate stacking structure 120 may have a structure in which the channel structure CH illustrated in FIG. 3 is disposed in a vertically inverted manner. Accordingly, in a cross-sectional view, the channel structure CH may have an inclined side surface such that a width of the channel structure CH decreases as the channel structure CH goes toward the circuit region 200. A channel pad 144 and a second wiring portion 180 that is disposed at an upper portion of the gate stacking structure 120 may be at a side far away from the circuit region 200a.

In implementations, the circuit region 200 might not include a first bonding structure 290 (refer to FIG. 3) and a first bonding insulation layer 292 (refer to FIG. 3), and the cell region 100f might not include a through via 110a, a source connecting portion 110b (refer to FIG. 3), an outer insulation layer 110c (refer to FIG. 3), a second bonding structure 190 (refer to FIG. 3), and a second bonding insulation layer 192 (refer to FIG. 3).

The semiconductor device 10f may be formed by not forming a portion of the cell region 100f in a non-stacked region NS (refer to FIG. 1) in a process of forming the cell region 100f on the circuit region 200. In some implementations, the semiconductor device 10f may be formed by forming the cell region 100f on the circuit region 200 and then removing a portion of the cell region 100f corresponding to the non-stacked region NS. Various other modifications are possible.

An example of an electronic system including the semiconductor device will be described in detail below.

FIG. 16 schematically illustrates an electronic system including a semiconductor device according to implementations.

Referring to FIG. 16, an electronic system 1000 according to implementations may include a semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid-state drive (SSD) device, a universal serial bus (USB), a computing system, a medical device, or a communication device including one or a plurality of semiconductor devices 1100.

The semiconductor device 1100 may be a non-volatile memory device, and for example, may be a NAND flash memory device described with reference to FIG. 1 to FIG. 15. The semiconductor device 1100 may include a first structure 1100F and a second structure 1100S on the first structure 1100F. In some implementations, the first structure 1100F may be next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified according to implementations.

In implementations, the lower transistors LT1 and LT2 may include a ground selection transistor, and the upper transistors UT1 and UT2 may include a string selection transistor. The first and second gate lower lines LL1 and LL2 may be gate lines of the lower transistors LT1 and LT2, respectively. The word line WL may be a gate line of the memory cell transistor MCT, and the gate upper lines UL1 and UL2 may be gate lines of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 extending to the second structure 1100S from the first structure 1100F. The bit line BL may be electrically connected to the page buffer 1120 through a second connection wiring 1125 extending to the second structure 1100S from the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 extending to the second structure 1100S from the first structure 1100F.

The controller 1200 may include a processor 1210, a NAND controller 1220, and a host interface 1230. According to implementations, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or so on may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

FIG. 17 is a perspective view schematically illustrating an electronic system including a semiconductor device according to implementations.

Referring to FIG. 17, an electronic system 2000 according to implementations may include a main substrate 2001, a controller 2002 on the main substrate 2001, one or more semiconductor packages 2003, and a DRAM 2004. The semiconductor package 2003 and the DRAM 2004 may be connected to the controller 2002 through a wiring pattern 2005 at the main substrate 2001.

The main substrate 2001 may include a connector 2006 including a plurality of pins coupled to the external host. A number and an arrangement of the plurality of pins in the connector 2006 may vary depending on a communication interface between the electronic system 2000 and the external host. In implementations, the electronic system 2000 may communicate with the external host according to any one of interfaces such as a universal serial bus (USB), a peripheral component interconnect express (PCI-Express), a serial advanced technology attachment (SATA), and an M-Phy for a universal flash storage (UFS). In implementations, the electronic system 2000 may operate by power supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003 and may improve an operating speed of the electronic system 2000.

The DRAM 2004 may be a buffer memory for mitigating or buffering a speed difference between the semiconductor package 2003, which is a data storage space, and the external host. The DRAM 2004 included in the electronic system 2000 may also be a kind of cache memory and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality Each of the first and second semiconductor packages 2003a and of semiconductor chips 2200a. 2003b may include a package substrate 2100, a stacking structure 2200 for a package on the package substrate 2100, and a molding layer 2500 covering the stacking structure 2200 for the package on the package substrate 2100.

The package substrate 2100 may be a printed circuit board including a package upper pad 2130 (refer to FIG. 18). Each of the semiconductor chips 2200a may include a gate stacking structure 4210 (refer to FIG. 18) and a channel structure 4220 (refer to FIG. 18). The semiconductor chip 2200a or the stacking structure 2200 for the package may include a semiconductor device or a stacking structure for a package described with reference to FIG. 1 to FIG. 15.

In implementations, the plurality of semiconductor chips 2200a included in the semiconductor package 2003 may be connected to each other by using a through connecting portion 4280 (refer to FIG. 18) and/or an interconnection member 4288 (refer to FIG. 18). The semiconductor chip 2200a and the package upper pad 2130 of package substrate 2100 may be electrically connected by the through connecting portion 4280 and/or the interconnection member 4288. However, the implementations are not limited thereto. The through connecting portion 4280 included in at least one of the plurality of semiconductor chips 2200a may be electrically connected to the package upper pad 2130 of package substrate 2100 by a separate connection structure. For example, the connection structure may be or include a bonding wire.

In implementations, the plurality of semiconductor chips 2200a included in the semiconductor package 2003 may be bonded to each other by a bonding layer 4320 (refer to FIG. 18). The stacking structure 2200 for the package and the package substrate 2100 may be bonded to each other by the bonding layer 4320. However, the implementations are not limited thereto. The plurality of semiconductor chips 2200a or the stacking structure 2200 for the package may be bonded to or physically fixed to the package substrate 2100 by any of various structures.

In implementations, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring at the interposer substrate.

FIG. 18 is a cross-sectional view schematically illustrating a semiconductor package according to implementations.

Referring to FIG. 18, in the semiconductor package 2003, the package substrate 2100 may be a printed circuit board. The package substrate 2100 may include a package substrate body portion 2120, a package upper pad 2130 at an upper surface of the package substrate body portion 2120, a package lower pad 2125 disposed at a lower surface of the package substrate body portion 2120 or exposed through the lower surface of the package substrate body portion 2120, and an internal wiring 2135 electrically connecting the package upper pad 2130 and the package lower pad 2125 inside the package substrate body portion 2120. The package upper pad 2130 may be electrically connected to the through connecting portion 4280 and/or the interconnection member 4288. The package lower pad 2125 may be connected to a wiring pattern 2005 of the main substrate 2001 of the electronic system 2000, as illustrated in FIG. 17, through a conductive connection portion 2800.

In a semiconductor package 2003, each semiconductor chip 2200a may include a semiconductor substrate 4010, a first structure 4100 on the semiconductor substrate 4010, and a second structure 4200 disposed on the first structure 4100 and bonded to the first structure 4100 by a wafer bonding type.

The first structure 4100 may include a peripheral circuit region including a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 passing through the gate stacking structure 4210, and a second bonding structure 4250 electrically connected to the channel structure 4220 and a word line WL (refer to FIG. 16) of the gate stacking structure 4210. For example, the second bonding structure 4250 may be electrically connected to the channel structure 4220 and the word line WL through a bit line 4240 electrically connected to the channel structure 4220 and a gate connection wiring electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In implementations, the plurality of package chips 2220a are stacked using the bonding layer or so on to form the stacking structure 2200. The stacking structure 2200 for the package may be electrically connected to the package substrate 2100 and the molding layer 2500 may be formed to form the semiconductor package 2003. However, the implementations are not limited thereto. The semiconductor package 2003 may be formed by any of various methods.

In implementations, a plurality of semiconductor devices or semiconductor chips 2200a may be connected by using a pad region in a non-stacked region having a relatively small thickness, thereby reducing a thickness of the semiconductor package 2003. In this instance, the plurality of semiconductor devices or semiconductor chips 2200a may be electrically connected to each other by the through connecting portion 4280 included in the pad region, thereby shortening a signal path and reducing a problem such as a signal loss. Accordingly, performance of the semiconductor device or the semiconductor package may be enhanced.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While some examples have been described in connection with what is presently considered to be some practical implementations, it is to be understood that the disclosure is not limited to the disclosed implementations, and that that the disclosure is intended to cover various modifications and equivalent arrangements included within the spirit and scope of the appended claims.

What is claimed is:

1. A semiconductor device, comprising:
a circuit region including a pad region; and
a cell region including a memory cell structure on the circuit region,
wherein the semiconductor device includes a stacked region where the cell region is stacked on the circuit region and a non-stacked region where the pad region of the circuit region is positioned outside the stacked region.

2. The semiconductor device of claim 1, wherein an area of the circuit region is greater than an area of the cell region in a plan view, and
a thickness of the non-stacked region is less than a thickness of the stacked region.

3. The semiconductor device of claim 1, wherein the pad region includes a through connecting portion including a first portion that passes through at least a partial portion of the circuit region.

4. The semiconductor device of claim 3, wherein the through connecting portion includes
a bonding structure at a first surface of the circuit region,
the first portion extending from the bonding structure to a second surface of the circuit region opposite to the first surface of the circuit region, and
a pad at a side of the second surface of the circuit region.

5. The semiconductor device of claim 1, wherein the non-stacked region is at a side of one edge of the circuit region in a first direction and extends in a second direction that is transverse to the first direction in a plan view.

6. The semiconductor device of claim 5, wherein a width of the non-stacked region or the pad region in the first direction is less than a width of the stacked region or the cell region in the first direction.

7. The semiconductor device of claim 1, wherein an area of the non-stacked region or an area of the pad region is less than an area of the stacked region or an area of the cell region.

8. The semiconductor device of claim 1, wherein the semiconductor device has a short axis direction and a long axis direction that are transverse to each other in a plan view, and
the non-stacked region or the pad region is at a side of one edge in the short axis direction and extends in the long axis direction.

9. The semiconductor device of claim 1, wherein the semiconductor device has a short axis direction and a long axis direction that are transverse to each other in a plan view, and
the non-stacked region or the pad region is at a side of one edge in the long axis direction and extends in the short axis direction.

10. The semiconductor device of claim 1, wherein the semiconductor device has a first direction and a second direction that are transverse to each other in a plan view,
the non-stacked region includes a first region that is at a side of one edge in the first direction and extends in the second direction, and a second region that is at a side of one edge in the second direction and extends in the first direction, and
the pad region is at a corner portion where the first region and the second region cross each other.

11. The semiconductor device of claim 1, wherein the memory cell structure includes a stacking structure including a plurality of interlayer insulation layers and a plurality of gate electrodes alternately stacked on each other, and a channel structure extending through the stacking structure, and
where the cell region is bonded to the circuit region.

12. A semiconductor package, comprising:
a plurality of semiconductor devices including a first semiconductor device and a second semiconductor device,
wherein the first semiconductor device includes a first stacked region where a first cell region having a first memory cell structure is on a first circuit region and includes a first non-stacked region where a first pad region of the first circuit region is positioned outside the first stacked region,
wherein the second semiconductor device includes a second stacked region where a second cell region having a second memory cell structure is on a second circuit region and includes a second non-stacked region where a second pad region of the second circuit region is positioned outside the second stacked region, and
wherein the first semiconductor device and the second semiconductor device are electrically connected to each other by stacking the second pad region on the first pad region.

13. The semiconductor package of claim 12, wherein a first through connecting portion that passes through at least a partial portion of the first circuit region in the first pad region is electrically connected to a second through connecting portion that passes through at least a partial portion of the second circuit region in the second pad region.

14. The semiconductor package of claim 13, wherein the first or second through connecting portion includes
a bonding structure at a first surface of the first or second circuit region,
a first portion extending from the bonding structure to a second surface of the first or second circuit region opposite to the first surface of the first or second circuit region, and
a pad at a side of the second surface of the first or second circuit region, and
wherein the bonding structure of the first through connecting portion and the pad of the second through connecting portion are connected to each other through an interconnection member.

15. The semiconductor package of claim 12, wherein an area of the first or second non-stacked region, an area of the first or second pad region, or an area of a connecting region of the first semiconductor device and the second semiconductor device is less than an area of the first or second stacked region, an area of the first or second cell region, or an area of a non-overlapped region of the first semiconductor device and the second semiconductor device.

16. The semiconductor package of claim 12, wherein the first semiconductor device and the second semiconductor device have a symmetrical shape based on the first or second pad region in a plan view.

17. The semiconductor package of claim 12, wherein a distance between the first circuit region and the second circuit region in a thickness direction is less than a thickness of the cell region in the thickness direction.

18. The semiconductor package of claim 12, further comprising:
a third semiconductor device that includes
a third stacked region, wherein a third cell region including a third memory cell structure is on a third circuit region, and
a third non-stacked region, wherein a third pad region of the third circuit region is positioned outside the third stacked region,
wherein the first pad region is at one side of the first semiconductor device in a first direction, the second pad region is at the other side of the second semiconductor device in the first direction, and the third pad region is at the one side of the third semiconductor device in the first direction, and
the first semiconductor device, the second semiconductor device, and the third semiconductor device are electrically connected to each other by sequentially stacking the first pad region, the second pad region, and the third pad region.

19. The semiconductor package of claim 12, further comprising:
a third semiconductor device that includes
a third stacked region, wherein a third cell region including a third memory cell structure is on a third circuit region, and
a third non-stacked region, wherein a third pad region of the third circuit region is positioned outside the third stacked region; and
a fourth semiconductor device that includes
a fourth stacked region, wherein a fourth cell region including a fourth memory cell structure is on a fourth circuit region, and
a fourth non-stacked region, wherein a fourth pad region of the fourth circuit region is positioned outside the fourth stacked region,
wherein the first pad region is at a first corner portion adjacent to one side in a first direction and one side in a second direction that is transverse to the first direction in the first semiconductor device,
the second pad region is at a second corner portion adjacent to the one side in the first direction and the other side in the second direction in the second semiconductor device,
the third pad region is at a third corner portion adjacent to the other side in the first direction and the one side in the second direction in the third semiconductor device,
the fourth pad region is at a fourth corner portion adjacent to the other side in the first direction and the other side in the second direction in the fourth semiconductor device, and
the first semiconductor device, the second semiconductor device, the third semiconductor device, and the fourth semiconductor device are electrically connected to each other by sequentially stacking the first pad region, the second pad region, the third pad region, and the fourth pad region.

20. An electronic system, comprising:
a main substrate;
a semiconductor device on the main substrate; and
a controller electrically connected to the semiconductor device on the main substrate,
wherein the semiconductor device includes a circuit region including a pad region, and a cell region including a memory cell structure on the circuit region, and
the semiconductor device includes a stacked region where the cell region is on the circuit region and a non-stacked region where the pad region of the circuit region is positioned outside the stacked region.
